(19) United States
(12) Patent Application Publication
(10) Pub. No.: US 2012/0214290 A1
(43) Pub. Date: Aug. 23, 2012

(54) SUBSTRATE HOLDER, PAIR OF SUBSTRATE HOLDERS, SUBSTRATE BONDING APPARATUS AND METHOD FOR MANUFACTURING DEVICES

(76) Inventors: Isao Sugaya, Kawasaki-shi (JP); Junichi Chonan, Fukaya-shi (JP); Hidehiro Maeda, Yokohama-shi (JP); Keiichi Tanaka, Saitama-shi (JP); Tomoyuki Yasuda, Naka-gun (JP)

(21) Appl. No.: 13/355,247

(22) Filed: Jan. 20, 2012

Related U.S. Application Data
(63) Continuation of application No. PCT/JP2010/004675, filed on Jul. 21, 2010.

(30) Foreign Application Priority Data
Jul. 21, 2009 (JP) 2009-170513
Nov. 4, 2009 (JP) 2009-253439
Nov. 4, 2009 (JP) 2009-253440
Feb. 4, 2010 (JP) 2010-023510

(51) Int. Cl. H01L 21/02; H01L 21/683

(52) U.S. Cl. 438/455; 269/37; 257/E21.002

(57) ABSTRACT

Provided is a substrate holder pair comprising a first substrate holder that has a first holding portion holding a first substrate; a second substrate holder that has a second holding portion holding a second substrate to be bonded with the first substrate and that, together with the first substrate holder, sandwiches the first substrate and the second substrate; an engaging member that causes the first substrate holder to engage with the second substrate holder; and a dust inhibiting section inhibits dust generated by the engaging of the engaging member from entering between the first holding portion and the second holding portion.

### BACKGROUND

1. Technical Field

The present invention relates to a substrate holder, a substrate holder pair, a substrate bonding apparatus, and a device manufacturing method.

2. Background Art

As shown in Japanese Patent Application Publication No. H11-261000, Japanese Patent Application Publication No. 2005-251972, and Japanese Patent Application Publication No. 2007-115978, a known layered semiconductor apparatus is formed by layering semiconductor substrates that each have elements, circuits, and the like formed thereon. When layering the semiconductor substrates, a pair of semiconductor substrates supported by substrate holders are positioned with a degree of accuracy corresponding to the line width of the semiconductor circuits and then layered, after which the entirety of each substrate is heated and pressurized to achieve bonding. At this time, a positioning apparatus that fixes the position of the pair of semiconductor substrates and a heating and pressurizing apparatus that realizes the permanent bonding via pressurization and heating are used.

When two semiconductor substrates are layered, if even a small amount of dust is trapped between the semiconductor circuit regions facing each other, the circuit operations becomes unacceptable. Furthermore, this can lead to localized occurrences of insufficient pressurization and heating, resulting in insufficient bonding strength.

### SUMMARY

Therefore, it is an object of an aspect of the innovations herein to provide a substrate holder, a substrate holder pair, a substrate bonding apparatus, and a device manufacturing method, which are capable of overcoming the above drawbacks accompanying the related art. The above and other objects can be achieved by combinations described in the independent claims. The dependent claims define further advantageous and exemplary combinations of the innovations herein.

According to a first aspect of the present invention, provided is a substrate holder pair comprising a first substrate holder that has a first holding portion holding a first substrate; a second substrate holder that has a second holding portion holding a second substrate to be bonded with the first substrate and that, together with the first substrate holder, sandwiches the first substrate and the second substrate; an engaging member that causes the first substrate holder to engage with the second substrate holder; and a dust inhibiting section inhibits dust generated by the engaging of the engaging member from entering between the first holding portion and the second holding portion.

According to a second aspect of the present invention, provided is a substrate holder pair comprising a first substrate holder that has a first holding portion contacting a first substrate; a second substrate holder that has a second holding portion contacting a second substrate to be stacked on and bonded with the first substrate and that, together with the first substrate holder, sandwiches the first substrate and the second substrate; a first engaging section provided on the first substrate holder; and a second engaging section that engages with the first engaging section and is provided on the second substrate holder. A contact surface between the first engaging section and the second engaging section is positioned below a bonding surface between the first substrate and the second substrate in a direction of gravity.

According to a third aspect of the present invention, provided is a substrate bonding apparatus comprising a first substrate holder that has a first holding portion contacting a first substrate; a second substrate holder that has a second holding portion contacting a second substrate to be bonded with the first substrate and that, together with the first substrate holder, sandwiches the first substrate and the second substrate; an engaging member that causes the first substrate holder and the second substrate holder to engage with each other; a dust inhibiting section that inhibits dust generated by the engagement of the engaging member from entering between the first holding portion and the second holding portion; and a bonding section that bonds the first substrate held by the first substrate holder and the second substrate held by the second substrate holder to each other.

According to a fourth aspect of the present invention, provided is a substrate bonding apparatus comprising a fixing section that fixes the first substrate and the second substrate, which is to be bonded to the first substrate, in a stacked state; a dust inhibiting section that inhibits dust generated by the fixing of the fixing section from entering between the first substrate and the second substrate; and a bonding section that bonds the first substrate and the second substrate to each other.

According to a fifth aspect of the present invention, provided is a device manufacturing method comprising manufacturing a device by stacking two substrates, the method comprising mounting a first substrate on a first substrate holder including a first holding portion that contacts the first substrate and a first engaging section provided outside the first holding portion; mounting a second substrate on a second substrate holder including a second holding portion that contacts the second substrate and a second engaging section provided outside the second holding portion; stacking the two substrates and sandwiching the two substrates with the first substrate holder and the second substrate holder; and engaging the first engaging section and the second engaging section with each other. During the engaging, a dust inhibiting section is used to inhibit dust generated by the engaging of the first engaging section and the second engaging section from entering between the first holding portion and the second holding portion.

According to a sixth aspect of the present invention, provided is a substrate holder comprising a holder body having a holding region that holds a substrate; a fixing member that is provided outside the holding region and fixes the substrate and another substrate in a stacked state; and a dust inhibiting section that inhibits dust generated by the fixing of the fixing member from entering into the holding region.

According to a seventh aspect of the present invention, provided is a substrate holder that holds a substrate and is transported, comprising a holder body having a holding region that holds a substrate on a surface thereof; and a dust trapping electrode that traps dust by generating electrostatic force and is embedded in a dust trapping region, which is positioned on a side of the holding region of the holder body in a transportation direction of the substrate holder.

According to an eighth aspect of the present invention, provided is a substrate bonding apparatus comprising a holder body having a holding region that holds a substrate; a fixing member that is provided outside the holding region and fixes the substrate and another substrate in a stacked state; a dust inhibiting section that inhibits dust generated by the fixing of the fixing member from entering into the holding region; and a bonding section that bonds the substrate held by the holder body to the other substrate.

According to a ninth aspect of the present invention, provided is a device manufacturing method comprising manufacturing a device by stacking two substrates, the method comprising mounting one of the two substrates on a holding region of a substrate holder; stacking the one substrate held by the substrate holder and the other of the two substrates; and fixing the two substrates in the stacked state using a fixing member provided on the substrate holder. During the fixing, a dust inhibiting section of the substrate holder is used to inhibit dust generated by the fixing of the fixing member from entering the holding region.

The summary clause does not necessarily describe all necessary features of the embodiments of the present invention. The present invention may also be a sub-combination of the features described above.

### BRIEF DESCRIPTION OF THE DRAWINGS

FIG. 1 schematically shows a substrate bonding apparatus.

FIG. 2 is a planar view schematically showing a semiconductor wafer.

FIG. 3 is a planar view schematically showing the first substrate holder holding the first substrate.

FIG. 4 is a planar view schematically showing the second substrate holder holding the second substrate.

FIG. 5 is a cross-sectional view schematically showing a state immediately before the substrate holder pair is formed.

FIG. 6 is a cross-sectional view schematically showing a state immediately after formation of the substrate holder pair.

FIG. 7 is a perspective view schematically showing the magnet unit.

FIG. 8 is a perspective view schematically showing another example of a magnet unit.

FIG. 9 is a planar view schematically showing a flat spring of an attraction unit.

FIG. 10 is a perspective view schematically showing a state in which the flat spring is elastically deformed.

FIG. 11 is a perspective view including the attracting element when the flat spring of FIG. 10 is in the deformed state.

FIG. 12 is a perspective view schematically showing an exemplary arrangement of spherical protrusions on an attracting element.

FIG. 13 is a cross-sectional view showing the coupling operation between the magnet unit and the attraction unit.

FIG. 14 is a cross-sectional view showing the coupling operation between the magnet unit and the attraction unit.

FIG. 15 is a cross-sectional view schematically showing the engagement control unit.

FIG. 16 is a side view schematically showing a state in which the transport apparatus grips the substrate holder pair.

FIG. 17 is a side view schematically showing essential portions of the bonding apparatus.

FIG. 18 schematically shows a substrate bonding apparatus.

FIG. 19 is a planar view schematically showing a semiconductor wafer.

FIG. 20 is a planar view schematically showing the first substrate holder holding the first substrate.

FIG. 21 is a planar view schematically showing the second substrate holder holding the second substrate.

FIG. 22 is a cross-sectional view schematically showing a state immediately before the substrate holder pair is formed.

FIG. 23 is a cross-sectional view schematically showing a state immediately after formation of the substrate holder pair.

FIG. 24 is a perspective view schematically showing a magnet unit.

FIG. 25 is a planar view schematically showing a flat spring of an attraction unit.

FIG. 26 is a perspective view schematically showing a state in which the flat spring is elastically deformed.

FIG. 27 is a perspective view including the attracting element when the flat spring of FIG. 10 is in the deformed state.

FIG. 28 is a cross-sectional view showing the coupling operation between the magnet unit and the attraction unit.

FIG. 29 is a cross-sectional view showing the coupling operation between the magnet unit and the attraction unit.

FIG. 30 is a vertical cross-sectional view schematically showing the engagement control unit.

FIG. 31 is a side view schematically showing a state in which the transport apparatus grips the substrate holder pair.

FIG. 32 is a side view schematically showing essential portions of the bonding apparatus.

FIG. 33 is a planar view schematically showing a first substrate holder including a dust flow inhibiting mechanism, as a first modification.

FIG. 34 is a planar view schematically showing a first substrate holder including a dust flow inhibiting mechanism, as a second modification.

FIG. 35 is a planar view schematically showing a second substrate holder including a dust flow inhibiting mechanism according to the second modification.

FIG. 36 is a cross-sectional view schematically showing a state immediately after formation of the substrate holder pair according to the second modification.

FIG. 37 is a perspective view schematically showing a magnet unit including a dust flow inhibiting mechanism, as a third modification.

FIG. 38 is a cross-sectional view of a state in which the magnet unit with the shield attached thereto contacts the attraction unit.

FIG. 39 schematically shows a substrate bonding apparatus.

FIG. 40 is a planar view schematically showing a semiconductor wafer.

FIG. 41 is a planar view schematically showing the first substrate holder holding the first substrate.

FIG. 42 is a planar view schematically showing the second substrate holder holding the second substrate.

FIG. 43 is a cross-sectional view schematically showing a state immediately before the substrate holder pair is formed.

FIG. 44 is a cross-sectional view schematically showing a state immediately after formation of the substrate holder pair.

FIG. 45 is a perspective view schematically showing the magnet unit.

FIG. 46 is a planar view schematically showing a flat spring of the attraction unit.

FIG. 47 is a perspective view schematically showing a state in which the flat spring is elastically deformed.

FIG. 48 is a perspective view including the attracting element when the flat spring of FIG. 10 is in the deformed state.

FIG. 49 is a cross-sectional view showing the coupling operation between the magnet unit and the attraction unit.

FIG. 50 is a cross-sectional view showing the coupling operation between the magnet unit and the attraction unit.

FIG. 51 is a cross-sectional view schematically showing the engagement control unit.

FIG. 52 is a side view schematically showing a state in which the transport apparatus grips the substrate holder pair.

FIG. 53 is a side view schematically showing essential portions of the bonding apparatus.

FIG. 54 is a planar view schematically showing a first substrate holder including a dust trapping region, as a first modification.

FIG. 55 is a planar view schematically showing a first substrate holder including a dust trapping region, as a second modification.

FIG. 56 is a planar view schematically showing a first substrate holder including a dust trapping region, as a third modification.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

### First Embodiment

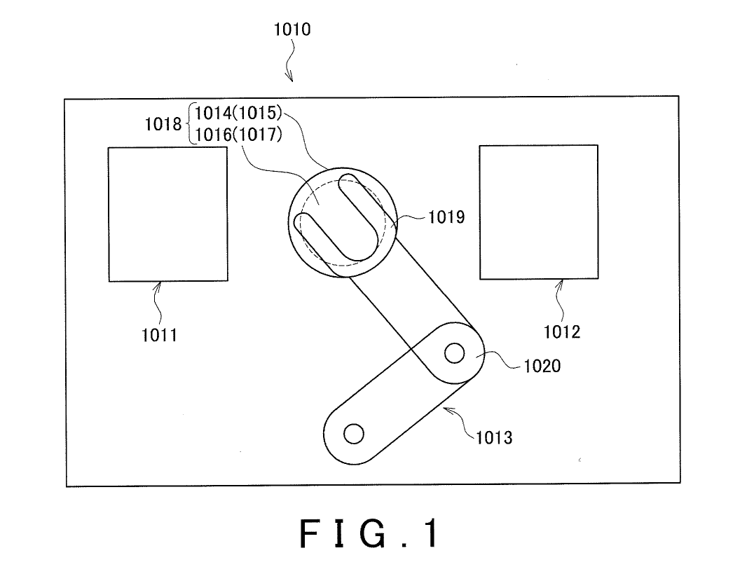

FIG. 1 schematically shows a substrate bonding apparatus 1010 according to a first embodiment. The substrate bonding apparatus 1010 includes an alignment apparatus 1011 that aligns a first substrate 1016, which is a semiconductor wafer, with a second substrate 1017, which is a semiconductor wafer to be layered on the first substrate 1016. The substrate bonding apparatus 1010 also includes a bonding apparatus 1012 that bonds together the first substrate 1016 and the second substrate 1017 aligned by the alignment apparatus 1011.

The first substrate 1016 is held by the first substrate holder 1014, and the second substrate 1017 is held by the second substrate holder 1015. In the alignment apparatus 1011, when the first substrate 1016 and the second substrate 1017 are aligned, the first substrate holder 1014 and the second substrate holder 1015 sandwich the first substrate 1016 and the second substrate 1017 to form these substrates integrally, thereby forming the substrate holder pair 1018. A detailed structure of the substrate holder pair 1018 is described further below.

The substrate bonding apparatus 1010 further includes a transport apparatus 1013 that transports the substrate holder pair 1018 integrated by the alignment apparatus 1011 to the bonding apparatus 1012. The transport apparatus 1013 can also transport a semiconductor wafer or a single substrate holder between apparatuses. The transport apparatus 1013 includes a gripping section 1019 that grips a gripping target such as the substrate holder pair 1018, and an arm portion 1020 that moves the gripping target to a prescribed position via rotating and extending/contracting movement.

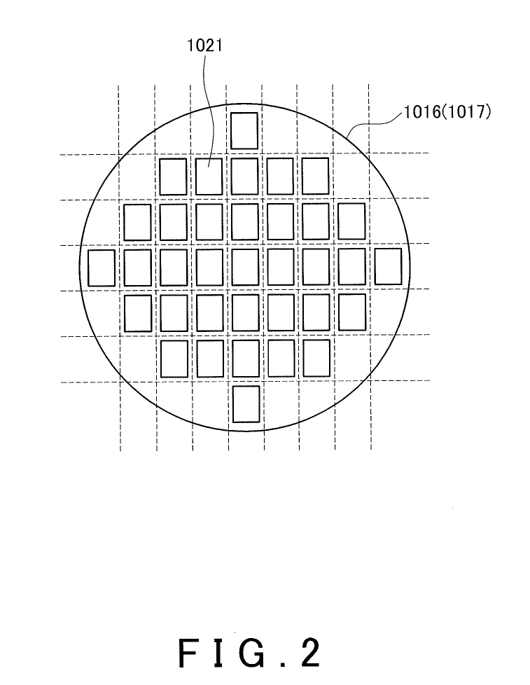

FIG. 2 is a planar view schematically showing a semiconductor wafer according to the present embodiment. The first substrate 1016 and the second substrate 1017, which are semiconductor wafers, are each formed of a circular thin board made of single-crystal silicon, and each have one surface on which a plurality of circuit regions 1021 are formed. The circuit regions 1021 are partitioned into a matrix, and circuit elements such as transistors, resistors, and capacitors are formed therein. The circuit elements are formed using mainly lithography techniques such as thin film formation, etching, or impurity diffusion. Alignment marks are provided within each of the circuit regions 1021. The alignment marks are indicators used to align the substrates with each other. The plurality of alignment marks provided on each of the first substrate 1016 and the second substrate 1017 have their set coordinate values stored independently and managed in a memory. The semiconductor wafers to be layered may be semiconductor wafers that have already been layered with other semiconductor wafers. In this case, the previously layered circuit layers preferably undergo a thinning process to remove unnecessary thickness.

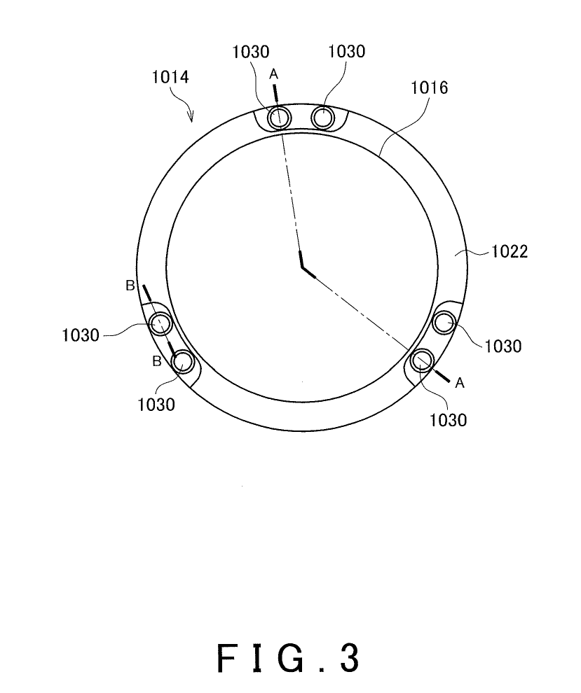

FIG. 3 is a planar view schematically showing the first substrate holder 1014 holding the first substrate 1016. The first substrate holder 1014 includes a holder body 1022 and an attraction unit 1030, and is shaped as a circular board with a diameter larger than that of the first substrate 1016. The holder body 1022 is formed integrally using a material with high rigidity such as ceramic or metal.

The holder body 1022 has a region for holding the first substrate 1016 on the surface thereof. This holding region is polished to be extremely flat. The holding of the first substrate 1016 is achieved by adhesion that uses electrostatic force. Specifically, voltage is applied to an electrode embedded in the holder body 1022, via a voltage application terminal provided on the back surface of the holder body 1022, to cause a potential difference between the first substrate holder 1014 and the first substrate 1016, thereby adhering the first substrate 1016 to the first substrate holder 1014. The adhesion surface of the first substrate 1016 is the surface opposite the surface on which the circuit regions 1021 are provided.

The attraction unit 1030 includes a plurality of peripheral regions, which are arranged further outward than the held first substrate 1016, on the surface thereof that holds the first substrate 1016. In the example shown in the drawings, sets that each include two attraction units 1030 are arranged at intervals of 120 degrees to obtain a total of six attraction units 1030. A more detailed configuration is described further below.

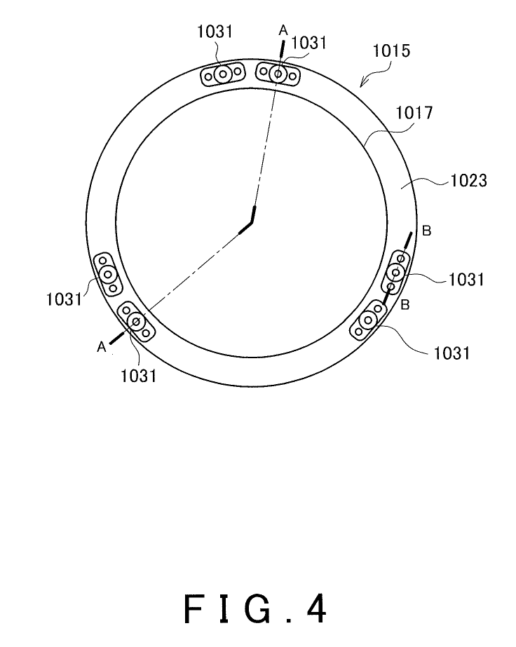

FIG. 4 is a planar view schematically showing the second substrate holder 1015 holding the second substrate 1017. The second substrate holder 1015 includes a holder body 1023 and magnet units 1031, and is shaped as a circular board with a diameter larger than that of the second substrate 1017. The holder body 1023 is formed integrally using a material with high rigidity such as ceramic or metal.

The holder body 1023 has a region for holding the second substrate 1017 on the surface thereof. This holding region is polished to be extremely flat. The holding of the second substrate 1017 is achieved by adhesion that uses electrostatic force. Specifically, voltage is applied to an electrode embedded in the holder body 1023, via a voltage application terminal provided on the back surface of the holder body 1023, to cause a potential difference between the second substrate holder 1015 and the second substrate 1017, thereby adhering the second substrate 1017 to the second substrate holder 1015. The adhesion surface of the second substrate 1017 is the surface opposite the surface on which the circuit regions 1021 are provided.

The magnet unit 1031 includes a plurality of peripheral regions, which are arranged further outward than the held second substrate 1017, on the surface thereof that holds the second substrate 1017. In the example shown in the drawings, sets that each include two magnet units 1031 are arranged at intervals of 120 degrees to obtain a total of six magnet units 1031.

The magnet units 1031 are arranged to correspond respectively to the attraction units 1030 of the first substrate holder 1014. When the first substrate holder 1014 holding the first substrate 1016 and the second substrate 1017 holding the second substrate holder 1015 face each other and the attraction units 1030 and magnet units 1031 are operated, the first substrate 1016 and the second substrate 1017 can be fixed together in a stacked state. This resulting stacked state is the substrate holder pair 1018. A more detailed configuration and the adhesion operation are described further below.

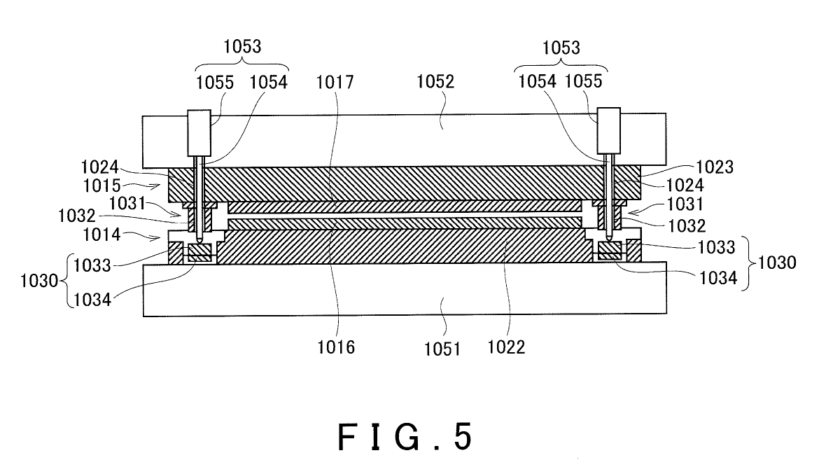

FIG. 5 is a cross-sectional view schematically showing a state immediately before the substrate holder pair 1018 is formed by the alignment apparatus 1011. Specifically, FIG. 5 is a cross-sectional view of a state in which the first substrate holder 1014 holding the first substrate 1016 is fixed to the first stage 1051 of the alignment apparatus 1011 by vacuum suction and the second substrate holder 1015 holding the second substrate 1017 is fixed to the second stage 1052 of the alignment apparatus 1011 by vacuum suction. In particular, the cross-sectional view is over the line A-A in FIGS. 3 and 4.

The first stage 1051 can move the first substrate 1016 relative to the second substrate 1017, in a Z-axis direction that is the layering direction and X-axis and Y-axis directions that are each orthogonal to the Z-axis. The alignment apparatus 1011 aligns the first substrate 1016 and the second substrate 1017, by using a first microscope arranged on the alignment apparatus 1011 in a manner to be able to observe the first substrate 1016 and a second microscope arranged on the alignment apparatus 1011 in a manner to be able to observe the second substrate 1017.

More specifically, each microscope is used to capture images of the alignment marks on each substrate serving as an observation target, and precise positions of the alignment marks are detected by performing image processing on the captured image data. The positional skew amount between corresponding alignment marks is then calculated and the first stage 1051 is moved according to this positional skew amount, thereby aligning the first substrate 1016 and the second substrate 1017. In this way, each circuit region 1021 of the first substrate 1016 faces a corresponding circuit region 1021 of the second substrate 1017. The positional skew amount calculation may be performed using a global alignment technique, for example, in which the positional skew amount is statistically determined to have a minimum value when the plurality of alignment marks of the first substrate 1016 overlap the plurality of alignment marks of the second substrate 1017.

When aligning the first substrate 1016 with the second substrate 1017, i.e. when moving the first stage 1051 in the XY-plane, a small gap is maintained between the first substrate 1016 and the second substrate 1017 such that the substrates do not contact each other. The second stage 1052 includes a plurality of engagement control units 1053, such that the attraction units 1030 do not engage with the magnet units 1031 when in this state.

Each engagement control unit 1053 is mainly formed from a push pin 1054, which is a member shaped as a pillar, and a cylinder portion 1055 that drives the push pin 1054. When at an extended position, the push pin 1054 passes through a holder insertion hole 1024 that is provided in the second substrate holder 1015 and a magnet insertion hole 1032 provided in the magnet unit 1031 arranged to be aligned with the holder insertion hole 1024, such that the tip of the push pin 1054 protrudes beyond the magnet insertion hole 1032. When at a storage position, a portion of the push pin 1054 is stored within the cylinder portion 1055, and is withdrawn from the insertion holes. In other words, the push pin 1054 moves back and forth in the Z-axis direction within the insertion holes, according to the drive of the cylinder portion 1055.

When the first substrate 1016 and the second substrate 1017 are to be moved relative to each other in the XY-plane, such as shown in FIG. 5, the push pins 1054 are held at the extended position in contact with the top surfaces of the attraction units 1030, thereby preventing the attraction units 1030 from engaging with the magnet units 1031. In other words, the attraction units 1030 are formed by attracting elements 1033 and flat springs 1034 fixed to the attracting elements 1033, but the push pins 1054 press on the attracting elements 1033 from above to restrict the elastic deformation of the flat springs 1034, such that the attracting elements 1033 do not engage with the magnet units 1031 as a result of the elastic deformation of the flat springs 1034.

The alignment of the first substrate 1016 and the second substrate 1017 by the alignment apparatus 1011 is performed at a final fine adjustment stage in which the movement amount is such that the tips of the push pins 1054 slide along the top surfaces of the attraction units 1030. At other stages, such as an observation stage in which the alignment marks are observed by the microscopes, the first substrate 1016 and the second substrate 1017 are separated from each other by a large amount in the X-, Y-, and Z-axis directions, and therefore the attraction units 1030 do not unexpectedly engage with the magnet units 1031. Accordingly, the push pins 1054 are held at the extended position when the magnetic force of the magnet units 1031 is exerted on the attraction units 1030 and engaging therebetween is to be prevented, and are held at the stored position at all other times.

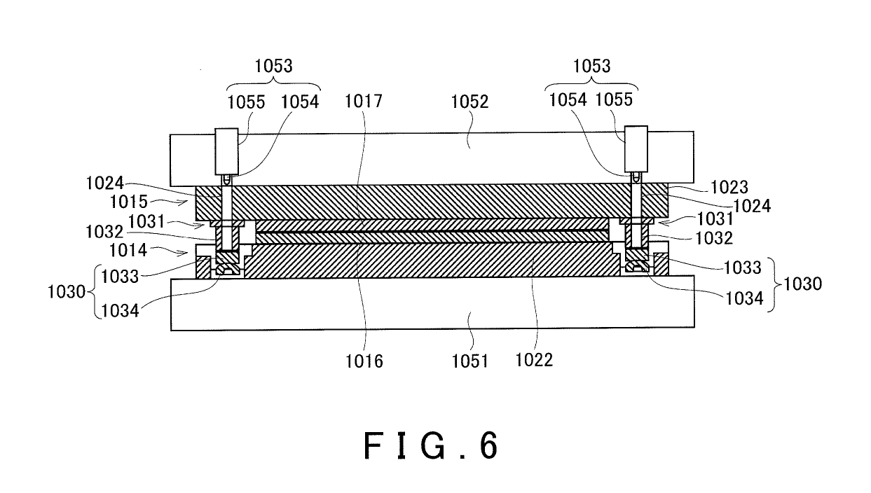

FIG. 6 is a cross-sectional view schematically showing a state immediately after formation of the substrate holder pair 1018 by the alignment apparatus 1011. Specifically, FIG. 6 shows a state in which the first stage 1051 has been driven in the Z-axis direction from the state shown in FIG. 5, such that the surface of the first substrate 1016 contacts the surface of the second substrate 1017, the push pins 1054 are held at the storage position, and the attraction units 1030 and magnet units 1031 are engaged.

During the process of transitioning from the state of FIG. 5 to the state of FIG. 6, the first substrate 1016 and the second substrate 1017 are aligned, and the magnet units 1031, which are engaging members, are engaged with the attraction units 1030, which are engagement receiving members. The first substrate holder 1014 and the second substrate holder 1015 are then formed integrally, thereby forming the substrate holder pair 1018 as the substrate holder system.

The Z-axis direction is the direction of gravitational force in the alignment apparatus 1011, and the first stage 1051 is positioned below the second stage 1052. Therefore, each surface is arranged from top to bottom, in the direction of the gravitational force, in the order of the second substrate 1017 holding surface of the second substrate holder 1015, the bonding surfaces of the second substrate 1017 and the first substrate 1016, and the first substrate 1016 holding surface of the first substrate holder 1014.

During the process of transitioning from the state of FIG. 5 to the state of FIG. 6, the movement of the push pins 1054 to the storage position causes elastic deformation of the flat springs 1034, and so the attraction units 1030 engage with the magnet units 1031. At this time, the engagement of the attracting elements 1033 of attraction units 1030 with the magnet units 1031 is accompanied by a small impact. Therefore, at this time, the contact surfaces of the attracting elements 1033 and the magnet units 1031 in the gravitational force direction are set to be lower than the contact surfaces of the second substrate 1017 and the first substrate 1016. The contact surfaces of the attracting elements 1033 and the magnet units 1031 are preferably set to be lower than the first substrate 1016 holding surface of the first substrate holder 1014.

By setting such a positional relationship, even if dust is created and scattered by the impact of the engagement between the attraction units 1030 and the magnet units 1031, the dust can be expected to be pulled down by gravity and to not enter between the first substrate 1016 and the second substrate 1017. In other words, dust entering between the substrates causes problems in the circuit operation and creates insufficient bonding strength, but these problems can be expected to be avoided by adopting the positional relationship described above.

Furthermore, when the contact surfaces of the attracting elements 1033 and the magnet units 1031 are set below the first substrate 1016 holding surface of the first substrate holder 1014, dust can be prevented from becoming attached to these surfaces. As a result, the first substrate holder 1014 can be kept in a clean state when used repeatedly, and there is no worry that dust will be trapped when the first substrate holder 1014 is mounted on another first substrate 1016. Accordingly, it can be expected that problems such as inclination of the first substrate 1016 and bonding unevenness in the bonding apparatus 1012 will be avoided.

After the substrate holder pair 1018 is formed, the substrate holder pair 1018 is released from the vacuum suction of the second stage 1052, lifted up by the first stage 1051, and transported to the bonding apparatus 1012 by the transport apparatus 1013. The transportation mechanism of the transport apparatus 1013 and the bonding process of the bonding apparatus 1012 are described further below.

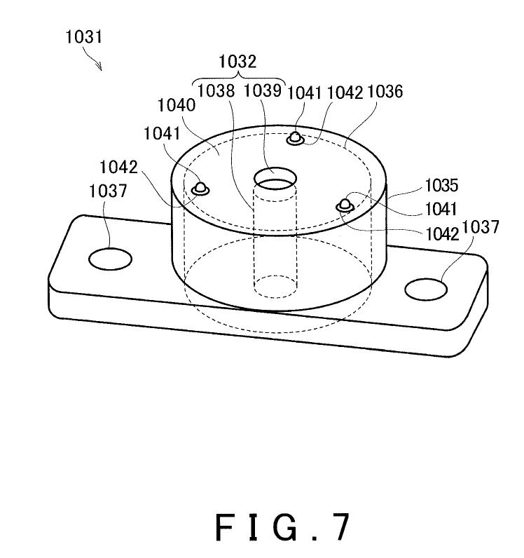

The following describes a configuration of the magnet unit 1031. FIG. 7 is a perspective view schematically showing the magnet unit 1031. The magnet unit 1031 includes a magnet 1036, a support section 1035 housing the magnet 1036, and a plurality of spherical protrusions 1041.

The support section 1035 includes a housing portion shaped as a circular cylinder that houses the magnet 1036, and a threaded hole 1037 through which passes a screw for fixing the support section 1035 to the second substrate 1017. The support section 1035 is formed by carbon steel S25C, for example. The magnet 1036 is a permanent magnet shaped as a circular pillar that can be inserted into the housing portion of the support section 1035, and may have a magnetic force of approximately 8 N, for example. The central axis of the magnet 1036 is provided with an insertion hole 1038 into which is inserted a push pin 1054, and an insertion hole 1039 in series with the insertion hole 1038 and into which the support section 1035 is inserted. The magnet insertion hole 1032 is formed by these two insertion holes.

The support section 1035 includes a counterface surface 1040 that faces the attracting element 1033. At least three spherical protrusions 1041 are embedded in the counterface surface 1040. The spherical protrusions 1041 are embedded and fixed by being pressed in fixing members 1042, which are brass rings formed on the counterface surface 1040, for example. As another example, the counterface surface 1040 of the support section 1035 may be machined using polishing, for example, such that the spherical protrusions 1041 are formed integrally with the support section 1035.

By forming the spherical protrusions 1041 in this way, point contact can be achieved between the magnet unit 1031 and the attracting element 1033. In other words, since the virtual surface formed by the spherical protrusions 1041 is the contact surface that contacts the attracting element 1033, the surface area of the contact can be greatly reduced, and the occurrence of dust can be significantly restricted.

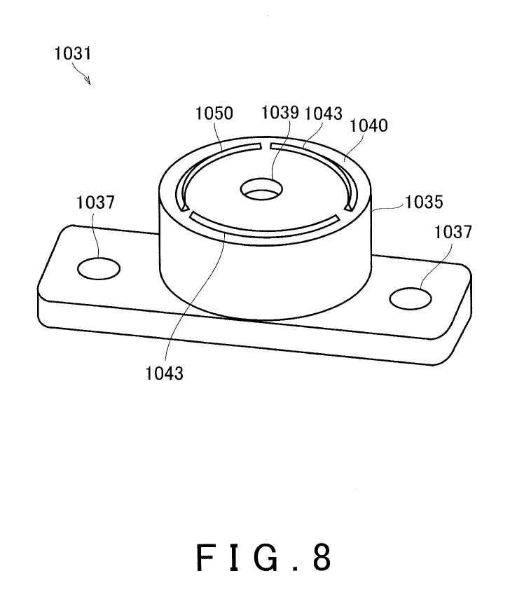

FIG. 8 is a perspective view schematically showing another example of a magnet unit 1031. This magnet unit 1031 differs from the magnet unit 1031 of FIG. 7 in that linear protrusions 1050, which are protruding portions having triangular cross sections, are formed on the counterface surface 1040. The linear protrusions 1050 may be formed integrally with the support section 1035 by machining the counterface surface 1040 of the support section 1035 via polishing, for example, or may be separate bodies attached to the counterface surface 1040.

By forming the linear protrusions 1050 in this way, line contact can be achieved between the magnet unit 1031 and the attracting element 1033. If the cross sections of the linear protrusions 1050 are triangular, for example, the virtual surface formed by a straight line connecting the peak edges is the contact surface that contacts the attracting element 1033, and therefore the surface area of the contact can be greatly reduced, and the occurrence of dust can be significantly restricted. The cross-sectional surface is not limited to a triangular shape, and any shape may be used that can achieve substantially linear contact. Furthermore, even if a small flat portion remains on the contact portion as a result of the polishing process, for example, this small flat portion is still acceptable as long as it can achieve substantially linear contact.

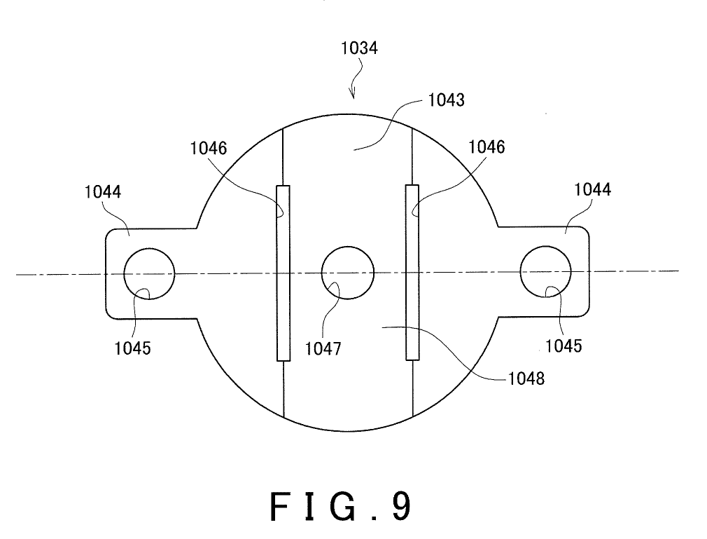

The following describes a configuration of an attraction unit 1030. FIG. 9 is a planar view schematically showing a flat spring 1034 of an attraction unit 1030.

The flat spring 1034 is an elastic member having elasticity in a direction orthogonal to the holding surface of the second substrate holder 1015 that holds the second substrate 1017, and may be formed of a high-strength precipitation-hardening stainless steel, such as SUS 631. The flat spring 1034 is formed by a central circular portion 1043 and attaching sections 1044 protruding therefrom as ears. The circular portion 1043 has a diameter of 22 mm and a thickness of 0.1 mm.

A pair of slits 1046 that extend in the same direction as each other are arranged in the circular portion 1043 with an interval therebetween in a direction orthogonal to the extension direction. Each slit 1046 is the same distance from the center of the circular portion 1043. The two slits 1046 form a band-shaped portion 1048 in the central region of the circular portion 1043. A through-hole 1047 that fixes the attracting element 1033 is formed in the band-shaped portion 1048 at the center of the circular portion 1043. Similarly, each attaching section 1044 includes a threaded hole 1045 through which passes a screw for fixing the flat spring 1034 to the second substrate holder 1015. The flat spring 1034 is arranged in a peripheral region of the holder body 1023, such that the two threaded holes 1045 are oriented along a circumferential direction of the second substrate holder 1015 and the extension direction of each slit 1046 is oriented along the radial direction of the second substrate holder 1015.

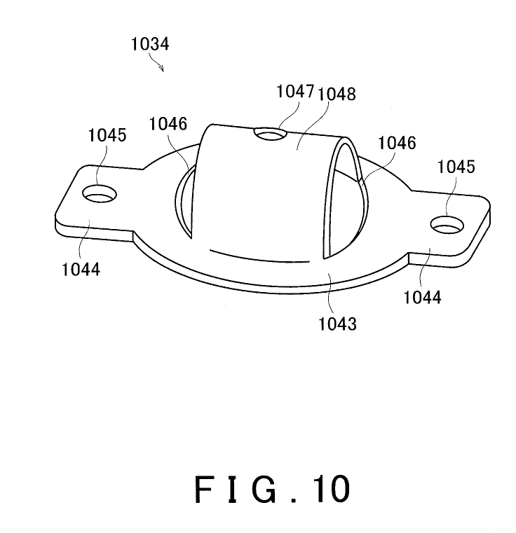

FIG. 10 is a perspective view schematically showing a state in which the flat spring 1034 is elastically deformed. Specifically, FIG. 10 shows a state in which the attracting element 1033 fixed to the flat spring 1034 is engaged with the magnet unit 1031 via attraction. It should be noted that the attracting element 1033 is not shown in FIG. 10.

In the flat spring 1034, as a result of the attracting element 1033 being attracted to the magnet unit 1031, the band-shaped portion 1048 rises upward such that that the through-hole 1047 becomes a peak, and the therefore two portions of the periphery of the circular portion 1043 connected to the band-shaped portion 1048 are deformed to draw closer to each other. At this time, the shapes of the openings in the slits 1046 are deformed to allow for the above deformation.

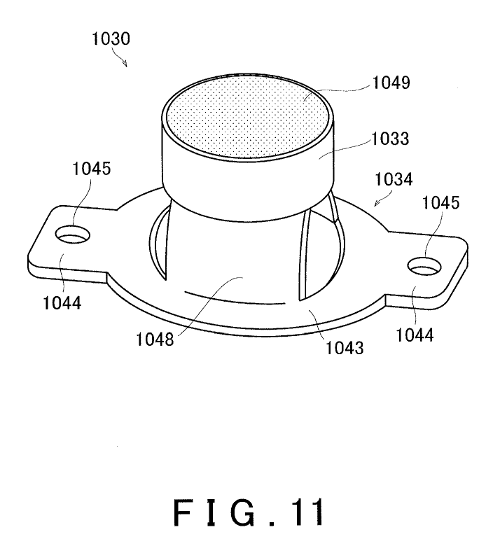

FIG. 11 is a perspective view including the attracting element 1033 when the flat spring 1034 of FIG. 10 is in the deformed state. The attracting element 1033 is fixed to the flat spring 1034 via the through-hole 1047, by a fastening member such as a screw.

The attracting element 1033 is formed of a ferromagnetic body, such as carbon steel S25C. A buffer plate 1049 is fixed to the contact surface of the attracting element 1033 that contacts the magnet unit 1031. The hardness of the buffer plate 1049 is less than that of the material forming the contact surface of the magnet unit 1031. For example, the material of the buffer plate may be a Si-type material or a resin material.

The buffer plate 1049 is preferably configured to be replaceable on the attracting element 1033. The buffer plate 1049 contacts the contact surface of the magnet unit 1031 and receives a focused stress, particularly when protruding portions such as the spherical protrusions 1041 or the linear protrusions 1050 are provided. Therefore, a depression or scraping can occur in the buffer plate 1049 as a result of the buffer plate 1049 absorbing the impact. Therefore, the buffer plate 1049 is replaced for every prescribed number of uses. The buffer plate 1049 is fixed by engaging with a recessed portion provided in the attracting element 1033 or by using an adhesive agent, for example.

In the above description, the support section 1035 of the magnet unit 1031 is provided with protruding portions such as the spherical protrusions 1041, and buffer plates 1049 are provided on the attracting element 1033 facing the protruding portions. However, the magnet unit 1031 and the attraction unit 1030, which are respectively the engaging member and the engagement receiving member, are in a relative relationship, and therefore the protruding portions and the buffer plates 1049 may each be formed on the opposite unit.

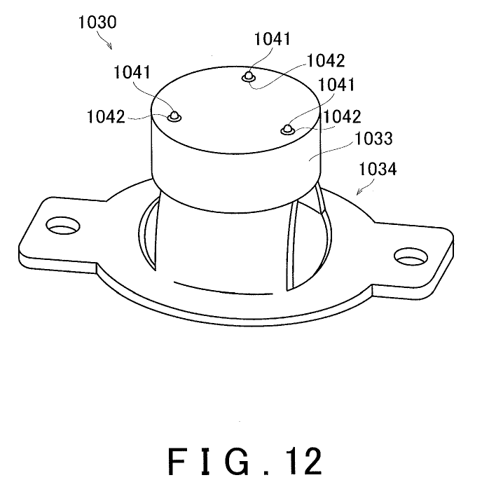

An example of this is provided in FIG. 12, which is a perspective view in which the spherical protrusions 1041 are arranged on the attracting element 1033. In the same manner as the example in which the spherical protrusions 1041 are provided on the support section 1035 of the magnet unit 1031, at least three spherical protrusions 1041 are embedded by being pressed in fixing members 1042, which are brass rings, for example. As another example, the spherical protrusions 1041 may be formed integrally with the attracting element 1033 by using machining such as polishing. With this configuration, the buffer plate 1049 is instead provided on the support section 1035 of the magnet unit 1031.

It should be noted that even if the positions of the protruding portions and the buffer plates 1049 are reversed, the contact surfaces of the attracting element 1033 and the magnet unit 1031 in the gravitational direction are still positioned to be below the bonding surfaces of the second substrate 1017 and the first substrate 1016. The contact surfaces are preferably positioned below the first substrate 1016 holding surface of the first substrate holder 1014.

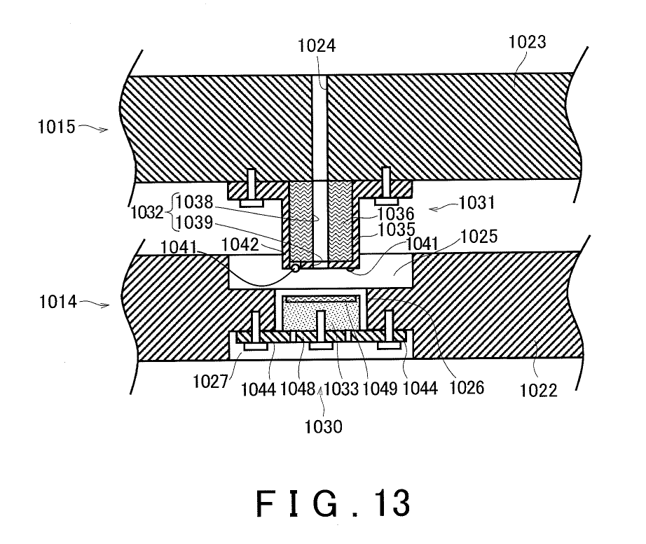

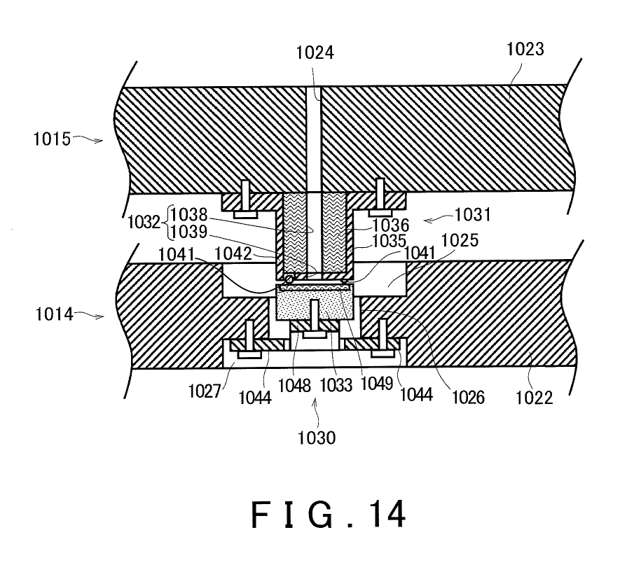

FIG. 13 is a cross-sectional view showing the coupling operation between the magnet unit 1031 and the attraction unit 1030. In particular, FIG. 13 shows a cross section over the line B-B in FIGS. 3 and 4. The first substrate 1016, the second substrate 1017, the push pin 1054, etc. are omitted from the drawing. FIG. 13 shows a state before the attracting element 1033 engages with the magnet unit 1031. FIG. 14 shows a state after the attracting element 1033 has engaged with the magnet unit 1031, using the same cross-sectional view as FIG. 13.

As shown in the drawings, the magnet unit 1031 is fixed to the surface of the second substrate holder 1015 by a screw. The flat surface that contacts the buffer plate 1049, which is the contact surface of the attracting element 1033, is the virtual flat surface formed by the peaks of the spherical protrusions 1041. This virtual flat surface is positioned below the first substrate 1016 holding surface of the first substrate holder 1014.

In other words, the first substrate holder 1014 includes a recessed portion 1025 having a surface that is lower than the first substrate 1016 holding surface and corresponding to the region in which the attraction unit 1030 is provided. The virtual surface formed by the peaks of the spherical protrusions 1041 is positioned within the recessed portion 1025 when the surface of the first substrate 1016 contacts the surface of the second substrate 1017.

The recessed portion 1025 includes a through-hole 1026 that allows the attracting element 1033 to move up and down. The back surface of the first substrate holder 1014, which is the side opposite the surface holding the first substrate 1016, includes a recessed portion 1027 around the through-hole 1026, and the flat spring 1034 and a screw fixing the flat spring 1034 to the first substrate holder 1014 are arranged to be housed within the recessed portion.

As shown by the change from the state of FIG. 13 to the state of FIG. 14, the band-shaped portion 1048 to which the attracting element 1033 is affixed elastically deforms as a result of the attracting element 1033 being attracted by the magnet 1036. At this time, the attaching sections 1044 are fixed to the first substrate holder 1014, and therefore the flat spring 1034 biases the first substrate holder 1014 and the second substrate holder 1015 to draw closer to each other, by sandwiching the second substrate 1017 with the first substrate 1016.

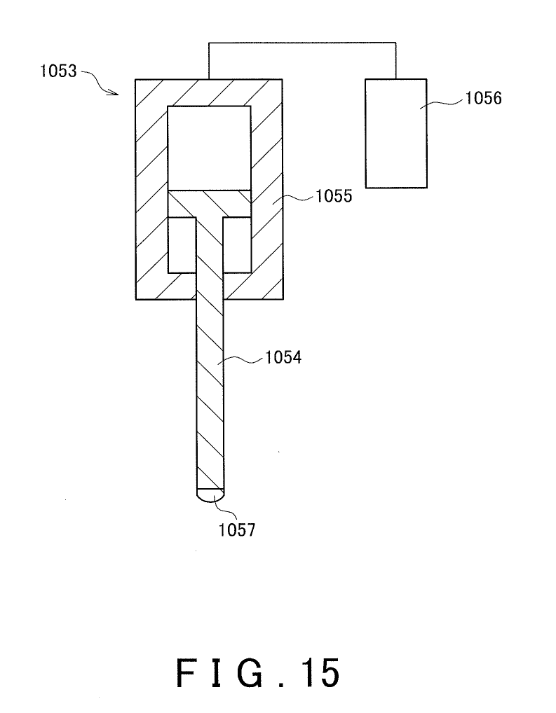

FIG. 15 is a cross-sectional view schematically showing the engagement control unit 1053. A plurality of engagement control units 1053 are arranged on the second substrate holder 1015, corresponding to the magnet units 1031. The cylinder portion 1055 is connected to an air pump 1056 that adjusts the atmospheric pressure within the cylinder portion 1055. The control section causes the push pin 1054 to extend and retract by controlling the air pump 1056. More specifically, the control section causes the push pin 1054 to be at the stored position in which at least a portion of the push pin 1054 is within the cylinder portion 1055 or at the extended position in which the tip 1057 of the push pin 1054 presses the buffer plate 1049. Accordingly, the pressing force exerted by the push pin 1054 on the buffer plate 1049 is large enough to resist the elastic force of the flat spring 1034.

The tip 1057 of the push pin 1054 is machined to be spherical, in order to achieve point contact with the buffer plate 1049. As another example, a tip portion such as a spherical protrusion 1041 may be provided as a separate member.

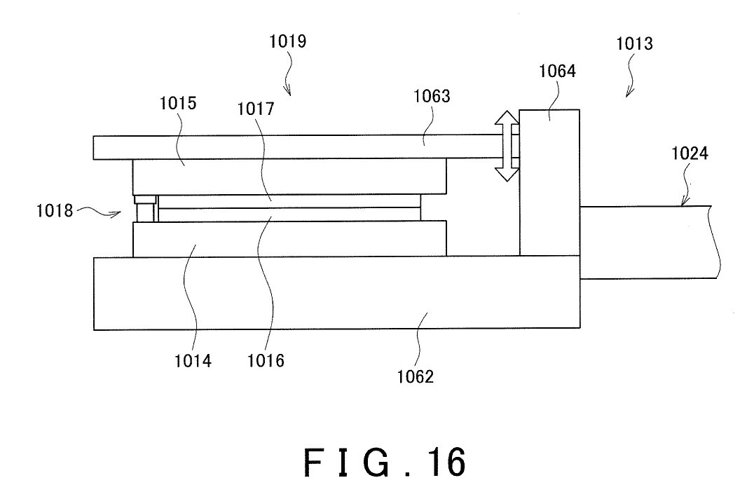

FIG. 16 is a side view schematically showing a state in which the transport apparatus 1013 grips the substrate holder pair 1018. The transport apparatus 1013 includes an arm portion 1020 and a gripping section 1019 that is connected to the arm portion 1020. The gripping section 1019 includes a support board 1062 that supports the substrate holder pair 1018 from below and a presser plate 1063 that presses the substrate holder pair 1018 from above. The support board 1062 includes a suction hole that fixes the substrate holder pair 1018 thereto using vacuum suction, and the substrate holder pair 1018 is fixed to the support board 1062 as a result of this suction.

The presser plate 1063 is provided on a support column 1064 formed on one end of the support board 1062, and can move back and forth in a direction to sandwich the substrate holder pair 1018. The presser plate 1063 exerts a pressing force on the substrate holder pair 1018 fixed to the support board 1062, such that the substrate holder pair 1018 can be sandwiched by the presser plate 1063 and the support board 1062. As a result of the arm portion 1020 moving while in this state, the transport apparatus 1013 transports the substrate holder pair 1018 from the alignment apparatus 1011 to the bonding apparatus 1012.

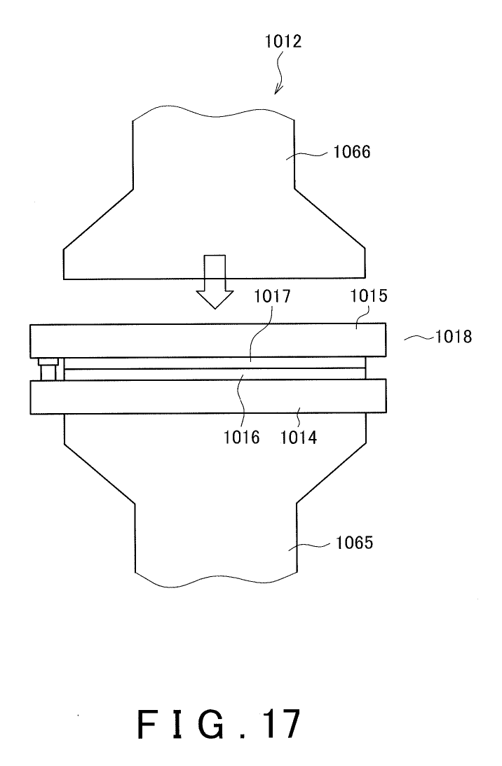

FIG. 17 is a side view schematically showing essential portions of the bonding apparatus 1012. The bonding apparatus 1012 includes a lower pressuring stage 1065 arranged below the first substrate holder 1014 and an upper pressuring stage 1066 arranged above the second substrate holder 1015. The upper pressuring stage 1066 can move toward the lower pressuring stage 1065, in order to apply pressure to the substrate holder pair 1018 together with the lower pressuring stage 1065. The lower pressuring stage 1065 and the upper pressuring stage 1066 each house a heater therein, and can therefore also apply heat to the substrate holder pair 1018 mounted thereon in addition to applying pressure. As a result of the pressure and heat being applied to the substrate holder pair 1018, the electrodes of the first substrate 1016 and the second substrate 1017 in contact with each other are fused together. As a result, the corresponding circuit regions 1021 of the first substrate 1016 and the second substrate 1017 are bonded together.

As described above, the contact surface area between the attracting element 1033 and the magnet unit 1031 is relatively small, so that dust does not enter therebetween. Accordingly, the dust attached to the contact surface of the attracting element 1033 or the magnet unit 1031 is restricted from being broken up, fragmented, and scattered during the bonding. When the fragmenting and scattering of dust is restricted, the dust is restricted from flowing toward the substrate. In particular, when the dust is fragmented and scattered, there is a problem that wind force occurring during the attachment or detachment of the first substrate 1016 and the second substrate 1017 when transporting the substrate holder pair 1018, for example, causes the fragmented dust to be lifted and spread easily. The present embodiment described above reduces the likelihood of this problem occurring. Furthermore, if the dust caught between substrates can be reduced, reduction in the contact surface between the attracting element 1033 and the magnet unit 1031 during bonding can be restricted. Accordingly, the present embodiment is also useful for preventing the occurrence of new dust.

### Second Embodiment

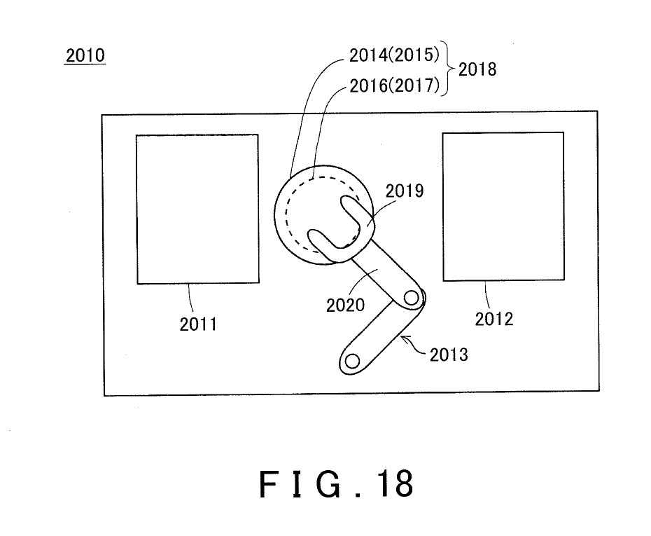

FIG. 18 schematically shows a substrate bonding apparatus 2010 according to a second embodiment. The substrate bonding apparatus 2010 includes an alignment apparatus 2011 that aligns a first substrate 2016, which is a semiconductor wafer, with a second substrate 2017, which is a semiconductor wafer to be layered on the first substrate 2016. The substrate bonding apparatus 2010 also includes a bonding apparatus 2012 that bonds together the first substrate 2016 and the second substrate 2017 aligned by the alignment apparatus 2011.

The first substrate 2016 is held by the first substrate holder 2014, and the second substrate 2017 is held by the second substrate holder 2015. In the alignment apparatus 2011, when the first substrate 2016 and the second substrate 2017 are aligned, the first substrate holder 2014 and the second substrate holder 2015 sandwich the first substrate 2016 and the second substrate 2017 to form these substrates integrally, thereby forming the substrate holder pair 2018. A detailed structure of the substrate holder pair 2018 is described further below.

The substrate bonding apparatus 2010 further includes a transport apparatus 2013 that transports the substrate holder pair 2018 integrated by the alignment apparatus 2011 to the bonding apparatus 2012. The transport apparatus 2013 can also transport a semiconductor wafer or a single substrate holder between apparatuses. The transport apparatus 2013 includes a gripping section 2019 that grips a gripping target such as the substrate holder pair 2018, and an arm portion 2020 that moves the gripping target to a prescribed position via rotating and extending/contracting movement.

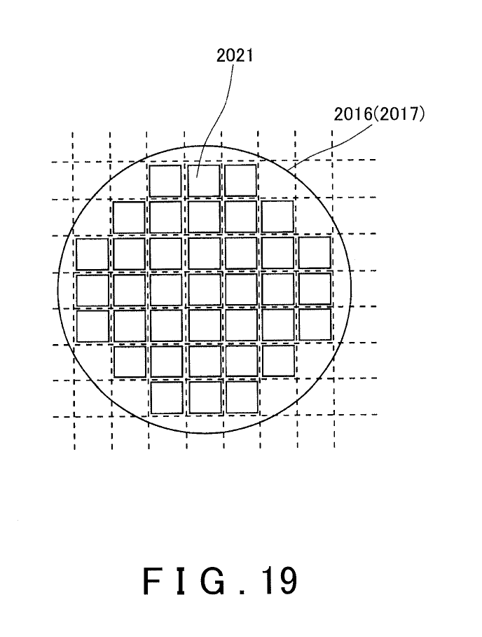

FIG. 19 is a planar view schematically showing a semiconductor wafer according to the present embodiment. The first substrate 2016 and the second substrate 2017, which are semiconductor wafers, are each formed of a circular thin board member made of single-crystal silicon, and each have one surface on which a plurality of circuit regions 2021 are formed. The circuit regions 2021 are partitioned into a matrix, and circuit elements such as transistors, resistors, and capacitors are formed therein. The circuit elements are formed using mainly lithography techniques such as thin film formation, etching, or impurity diffusion. Alignment marks are provided within each of the circuit regions 2021. The alignment marks are indicators used to align the substrates with each other. The plurality of alignment marks provided on each of the first substrate 2016 and the second substrate 2017 have their set coordinate values stored independently and managed in a memory. The semiconductor wafers to be layered may be semiconductor wafers that have already been layered with other semiconductor wafers. In this case, the previously layered circuit layers preferably undergo a thinning process to remove unnecessary thickness.

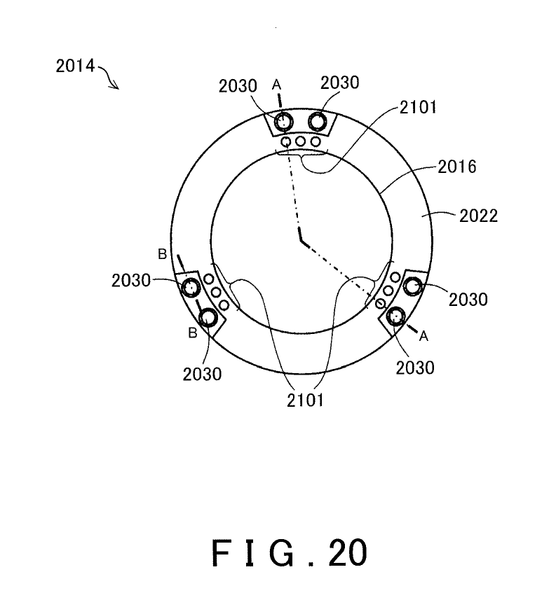

FIG. 20 is a planar view schematically showing the first substrate holder 2014 holding the first substrate 2016. The first substrate holder 2014 includes a holder body 2022 and an attraction unit 2030, which serves as an engaging section, and is shaped as a circular board with a diameter larger than that of the first substrate 2016. The holder body 2022 is formed integrally using a material with high rigidity such as ceramic or metal.

The holder body 2022 has a region for holding the first substrate 2016 on the surface thereof. This holding region is polished to be extremely flat. The holding of the first substrate 2016 is achieved by adhesion that uses electrostatic force. Specifically, voltage is applied to an electrode embedded in the holder body 2022, via a voltage application terminal provided on the back surface of the holder body 2022, to cause a potential difference between the first substrate holder 2014 and the first substrate 2016, thereby adhering the first substrate 2016 to the first substrate holder 2014. The adhesion surface of the first substrate 2016 is the surface opposite the surface on which the circuit regions 2021 are provided.

The attraction unit 2030 includes a plurality of peripheral regions, which are arranged further outward than the held first substrate 2016, on the surface thereof that holds the first substrate 2016. In the example shown in the drawings, sets that each include two attraction units 2030 are arranged at intervals of 120 degrees to obtain a total of six attraction units 2030. A more detailed configuration is described further below.

The first substrate holder 2014 includes first through-holes 2101 passing through the holder body 2022 in regions between the region holding the first substrate 2016 and the attraction units 2030. In the example of FIG. 20, three first through-holes 2101 are formed between each set of attraction units 2030 and the region holding the first substrate 2016, but the number of first through-holes 2101 provided may correspond to the number of attraction units 2030, and the first through-holes 2101 may be formed as elongated holes to correspond to the shape of the attraction unit 2030 sets.

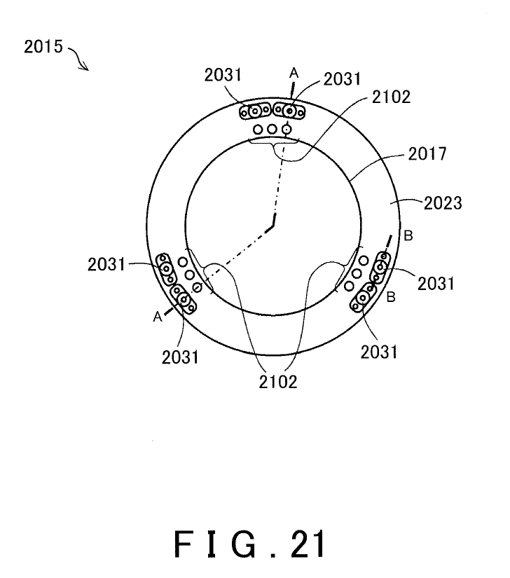

FIG. 21 is a planar view schematically showing the second substrate holder 2015 holding the second substrate 2017. The second substrate holder 2015 includes a holder body 2023 and magnet units 2031, which serve as engaging sections, and is shaped as a circular board with a diameter larger than that of the second substrate 2017. The holder body 2023 is formed integrally using a material with high rigidity such as ceramic or metal.

The holder body 2023 has a region for holding the second substrate 2017 on the surface thereof. This holding region is polished to be extremely flat. The holding of the second substrate 2017 is achieved by adhesion that uses electrostatic force. Specifically, voltage is applied to an electrode embedded in the holder body 2023, via a voltage application terminal provided on the back surface of the holder body 2023, to cause a potential difference between the second substrate holder 2015 and the second substrate 2017, thereby adhering the second substrate 2017 to the second substrate holder 2015. The adhesion surface of the second substrate 2017 is the surface opposite the surface on which the circuit regions 2021 are provided.

The magnet unit 2031 includes a plurality of peripheral regions, which are arranged further outward than the held second substrate 2017, on the surface thereof that holds the second substrate 2017. In the example shown in the drawings, sets that each include two magnet units 2031 are arranged at intervals of 120 degrees to obtain a total of six magnet units 2031.

The magnet units 2031 are arranged to correspond respectively to the attraction units 2030 of the first substrate holder 2014. When the first substrate holder 2014 holding the first substrate 2016 and the second substrate 2017 holding the second substrate holder 2015 face each other and the attraction units 2030 and magnet units 2031 are operated, the first substrate 2016 and the second substrate 2017 can be fixed together in a stacked state. This resulting stacked state is the substrate holder pair 2018. A more detailed configuration and the adhesion operation are described further below.

The second substrate holder 2015 includes second through-holes 2102 passing through the holder body 2023 in regions between the region holding the second substrate 2017 and the magnet units 2031. In the example of FIG. 21, three second through-holes 2102 are formed between each set of magnet units 2031 and a region holding the second substrate 2017, but the number of second through-holes 2102 provided may correspond to the number of magnet units 2031, and the second through-holes 2102 may be formed as elongated holes to correspond to the shape of the magnet unit 2031 sets. The first through-holes 2101 and the second through-holes 2102 form a dust flow inhibiting mechanism, and a detailed operation thereof is described further below.

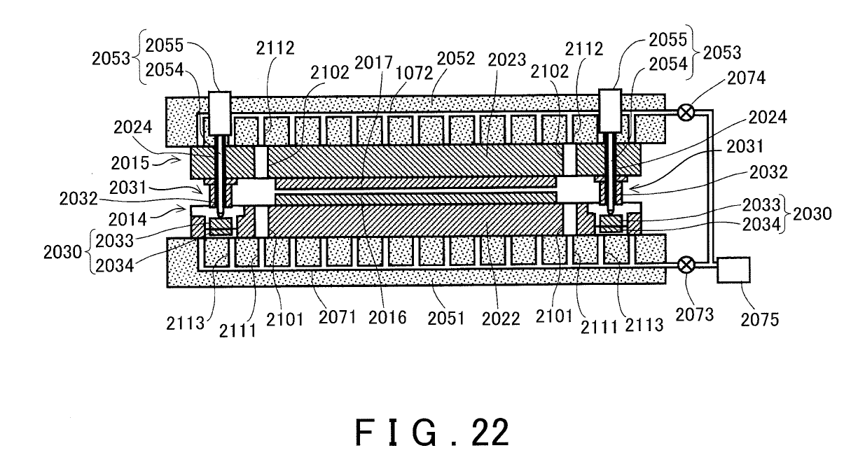

FIG. 22 is a cross-sectional view schematically showing a state immediately before the substrate holder pair 2018 is formed by the alignment apparatus 2011. Specifically, FIG. 22 is a cross-sectional view of a state in which the first substrate holder 2014 holding the first substrate 2016 is fixed to the first stage 2051 of the alignment apparatus 2011 by vacuum suction and the second substrate holder 2015 holding the second substrate 2017 is fixed to the second stage 2052 of the alignment apparatus 2011 by vacuum suction. In particular, the cross-sectional view is over the line A-A in FIGS. 20 and 21.

The first substrate holder 2014 is fixed to the front surface of the first stage 2051 by a vacuum suction force exerted by a suction apparatus 2075 via a first suction piping 2071 passing through the first stage 2051 to reach the front surface thereof. The first suction piping 2071 includes a plurality of branches reaching the front surface of the first stage 2051, and exerts uniform suction over a wide region on the back surface of the first substrate holder 2014. The suction force of the suction apparatus 2075 is adjusted by a first valve 2073, in order to control attachment and detachment of the first substrate holder 14.

Similarly, the second substrate holder 2015 is fixed to the front surface of the second stage 2052 by the vacuum suction force exerted by a suction apparatus 2075 via a second suction piping 2072 passing through the second stage 2052 to reach the front surface thereof. The second suction piping 2072 includes a plurality of branches reaching the front surface of the second stage 2052, and exerts uniform suction over a wide region on the back surface of the second substrate holder 2015. The suction force of the suction apparatus 2075 is adjusted by a second valve 2074, in order to control attachment and detachment of the second substrate holder 15.

The first stage 2051 can move the first substrate 2016 relative to the second substrate 2017, in a Z-axis direction that is the layering direction and X-axis and Y-axis directions that are each orthogonal to the Z-axis. The alignment apparatus 2011 aligns the first substrate 2016 and the second substrate 2017, by using a first microscope arranged on the alignment apparatus 2011 in a manner to be able to observe the first substrate 2016 and a second microscope arranged on the alignment apparatus 2011 in a manner to be able to observe the second substrate 2017.

More specifically, each microscope is used to capture images of the alignment marks on each substrate serving as an observation target, and precise positions of the alignment marks are detected by performing image processing on the captured image data. The positional skew amount between corresponding alignment marks is then calculated and the first stage 2051 is moved according to this positional skew amount, thereby aligning the first substrate 2016 and the second substrate 2017. In this way, each circuit region 2021 of the first substrate 2016 faces a corresponding circuit region 2021 of the second substrate 2017. The positional skew amount calculation may be performed using a global alignment technique, for example, in which the positional skew amount is statistically determined to have a minimum value when the plurality of alignment marks of the first substrate 2016 overlap the plurality of alignment marks of the second substrate 2017.

When aligning the first substrate 2016 with the second substrate 2017, i.e. when moving the first stage 2051 in the XY-plane, a small gap is maintained between the first substrate 2016 and the second substrate 2017 such that the substrates do not contact each other. The second stage 2052 includes a plurality of engagement control units 2053, such that the attraction units 2030 do not engage with the magnet units 2031 when in this state.

Each engagement control unit 2053 is mainly formed from a push pin 2054, which is a member shaped as a pillar, and a cylinder portion 2055 that drives the push pin 2054. When at an extended position, the push pin 2054 passes through a holder insertion hole 2024 that is provided in the second substrate holder 2015 and a magnet insertion hole 2032 provided in the magnet unit 2031 arranged to be aligned with the holder insertion hole 2024, such that the tip of the push pin 2054 protrudes beyond the magnet insertion hole 2032. When at a storage position, a portion of the push pin 2054 is stored within the cylinder portion 2055, and is withdrawn from the insertion holes. In other words, the push pin 2054 moves back and forth in the Z-axis direction within the insertion holes, according to the drive of the cylinder portion 2055.

When the first substrate 2016 and the second substrate 2017 are to be moved relative to each other in the XY-plane, such as shown in FIG. 22, the push pins 2054 are held at the extended position in contact with the top surfaces of the attraction units 2030, thereby preventing the attraction units 2030 from engaging with the magnet units 2031. In other words, the attraction units 2030 are formed by attracting elements 2033 and flat springs 2034 fixed to the attracting elements 2033, but the push pins 2054 press on the attracting elements 2033 from above to restrict the elastic deformation of the flat springs 2034, such that the attracting elements 2033 do not engage with the magnet units 2031 as a result of the elastic deformation of the flat springs 2034.

The alignment of the first substrate 2016 and the second substrate 2017 by the alignment apparatus 2011 is performed at a final fine adjustment stage in which the movement amount is such that the tips of the push pins 2054 slide along the top surfaces of the attraction units 2030. At other stages, such as an observation stage in which the alignment marks are observed by the microscopes, the first substrate 2016 and the second substrate 2017 are separated from each other by a large amount in the X-, Y-, and Z-axis directions, and therefore the attraction units 2030 do not unexpectedly engage with the magnet units 2031. Accordingly, the push pins 2054 are held at the extended position when the magnetic force of the magnet units 2031 is exerted on the attraction units 2030 and engaging therebetween is to be prevented, and are held at the stored position at all other times.

A portion of the tubes branching from the first suction piping 2071 and connected to the front surface of the first stage 2051 are connected as first communicating tubes 2111 to the first through-hole 2101 of the first substrate holder 2014 fixed to the first stage 2051. A portion of the tubes branching from the second suction piping 2072 and connected to the front surface of the second stage 2052 are connected as second communicating tubes 2112 to the second through-hole 2102 of the second substrate holder 2015 fixed to the second stage 2052. Another portion of the tubes branching from the first suction piping 2071 and connected to the front surface of the first stage 2051 are connected as third communicating tubes 2113 to an empty space on the back surface side of the flat spring 2034 of the first substrate holder 2014 fixed to the first stage 2051.

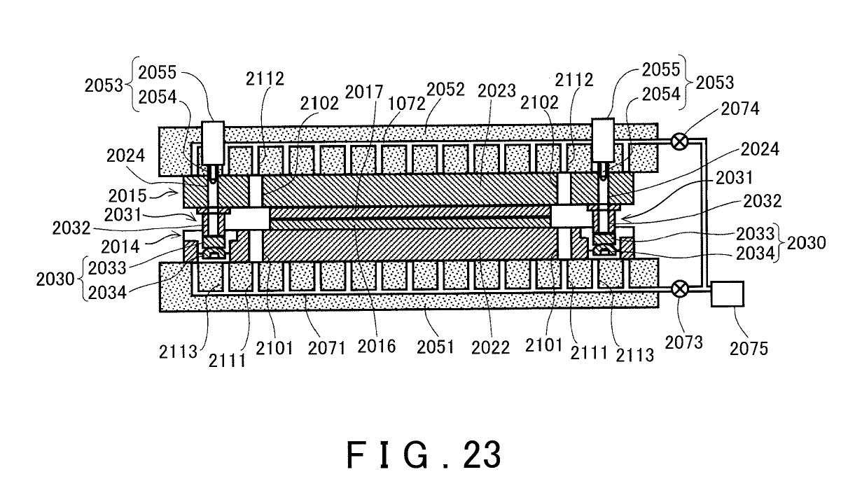

FIG. 23 is a cross-sectional view schematically showing a state immediately after formation of the substrate holder pair 2018 by the alignment apparatus 2011. Specifically, FIG. 23 shows a state in which the first stage 2051 has been driven in the Z-axis direction from the state shown in FIG. 22, such that the surface of the first substrate 2016 contacts the surface of the second substrate 2017, the push pins 2054 are held at the storage position, and the attraction units 2030 and magnet units 2031 are engaged.

During the process of transitioning from the state of FIG. 22 to the state of FIG. 23, the first substrate 2016 and the second substrate 2017 are aligned, and the magnet units 2031, which are engaging members, are engaged with the attraction units 2030, which are engagement receiving members. The first substrate holder 2014 and the second substrate holder 2015 are then formed integrally, thereby forming the substrate holder pair 2018 as the substrate holder system.

The Z-axis direction is the direction of gravitational force in the alignment apparatus 2011, and the first stage 2051 is positioned below the second stage 2052. Therefore, each surface is arranged from top to bottom, in the direction of the gravitational force, in the order of the second substrate 2017 holding surface of the second substrate holder 2015, the bonding surfaces of the second substrate 2017 and the first substrate 2016, and the first substrate 2016 holding surface of the first substrate holder 2014.

During the process of transitioning from the state of FIG. 22 to the state of FIG. 23, the movement of the push pins 2054 to the storage position causes elastic deformation of the flat springs 2034, and so the attraction units 2030 engage with the magnet units 2031. At this time, the engagement of the attracting elements 2033 of the attraction units 2030 with the magnet units 2031 is accompanied by a small impact. Therefore, at this time, the contact surfaces of the attracting elements 2033 and the magnet units 2031 in the gravitational force direction are set to be lower than the contact surfaces of the second substrate 2017 and the first substrate 2016. The contact surfaces of the attracting elements 2033 and the magnet units 2031 are preferably set to be lower than the first substrate 2016 holding surface of the first substrate holder 2014.

By setting such a positional relationship, even if dust is created and scattered by the impact of the engagement between the attraction units 2030 and the magnet units 2031, the dust can be expected to be pulled down by gravity and to not enter between the first substrate 2016 and the second substrate 2017. Even if some dust moves from the space between the first substrate holder 2014 and the second substrate holder 2015 toward the first substrate 2016 and the second substrate 2017, this dust can be expected to be withdrawn from the first through-holes 2101 and the second through-holes 2102.

Specifically, the first through-holes 2101 connected to the first communicating tubes 2111 and the second through-holes 2102 connected to the second communicating tubes 2112 exert suction due to the operation of the suction apparatus 2075, and suck in the atmosphere near the openings thereof. When some of the dust generated by the impact of the bonding between the attraction unit 2030 and the magnet unit 2031 passes near the opening of the first through-holes 2101 and the second through-holes 2102, the this dust is sucked into the openings along with the nearby atmosphere and withdrawn into the first suction piping 2071 or the second suction piping 2072. In other words, the generated dust can be expected to be withdrawn before entering between the first substrate 2016 and the second substrate 2017. Dust entering between the substrates causes problems in the circuit operation and insufficient bonding strength, but these problems can be ameliorated by adopting the configuration described above.

Furthermore, the third communicating tubes 2113 are connected to an empty space on the back surface side of the flat spring 2034, and therefore the dust generated by the impact of the bonding between the attraction unit 2030 and the magnet unit 2031 can also be expected to be withdrawn by the third communicating tubes 2113. In other words, the third communicating tubes 2113 also exert suction due to the operation of the suction apparatus 2075 to suck in atmosphere from the empty space on the back surface side of the flat spring 2034, and therefore the generated dust is withdrawn to the first suction piping 2071 along with the suctioned atmosphere.

The suction force of the first suction piping 2071 and the second suction piping 2072 may be strengthened during a prescribed period beginning when the attraction unit 2030 and the magnet unit 2031 are engaged, by adjusting the first valve 2073 and the second valve 2074. By strengthening the suction force in this way, the dust can be withdrawn more reliably.

After the substrate holder pair 2018 is formed, the substrate holder pair 2018 is released from the vacuum suction of the second stage 2052, lifted up by the first stage 2051, and transported to the bonding apparatus 2012 by the transport apparatus 2013. The transportation mechanism of the transport apparatus 2013 and the bonding process of the bonding apparatus 2012 are described further below.

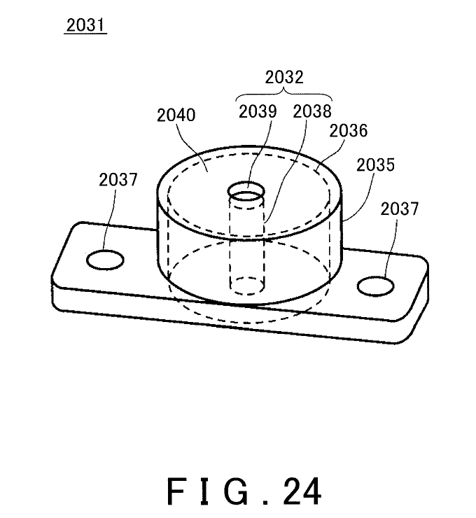

The following describes a configuration of the magnet unit 2031. FIG. 24 is a perspective view schematically showing the magnet unit 2031. The magnet unit 2031 includes a magnet 2036 and a support section 2035 housing the magnet 2036.

The support section 2035 includes a housing portion shaped as a circular cylinder that houses the magnet 2036, and a threaded hole 2037 through which passes a screw for fixing the support section 2035 to second substrate holder 2015. The support section 2035 is formed by carbon steel S25C, for example. The support section 2035 has a counterface surface 2040 facing the attracting element 2033. The magnet 2036 is a permanent magnet shaped as a circular pillar that can be inserted into the housing portion of the support section 2035, and may have a magnetic force of approximately 8 N, for example. The central axis of the magnet 2036 is provided with an insertion hole 2038 into which is inserted a push pin 2054, and an insertion hole 2039 in series with the insertion hole 2038 and into which the support section 2035 is inserted. The magnet insertion hole 2032 is formed by these two insertion holes.

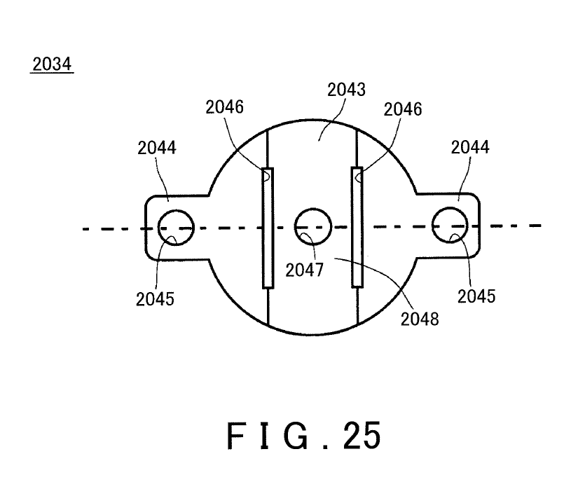

The following describes a configuration of an attraction unit 2030. FIG. 25 is a planar view schematically showing a flat spring 2034 of an attraction unit 2030. The flat spring 2034 is an elastic member having elasticity in a direction orthogonal to the holding surface of the second substrate holder 2015 that holds the second substrate 2017, and may be formed of a high-strength precipitation-hardening stainless steel, such as SUS 631. The flat spring 2034 is formed by a central circular portion 43 and attaching sections 2044 protruding therefrom as ears. The circular portion 43 has a diameter of 22 mm and a thickness of 0.1 mm.

A pair of slits 2046 that extend in the same direction as each other are arranged in the circular portion 43 with an interval therebetween in a direction orthogonal to the extension direction. Each slit 2046 is the same distance from the center of the circular portion 43. The two slits 2046 form a band-shaped portion 2048 in the central region of the circular portion 43. A through-hole 2047 that fixes the attracting element 2033 is formed in the band-shaped portion 2048 at the center of the circular portion 43. Similarly, each attaching section 2044 includes a threaded hole 2045 through which passes a screw for fixing the flat spring 2034 to the second substrate holder 2015. The flat spring 2034 is arranged in a peripheral region of the holder body 2023, such that the two threaded holes 2045 are oriented along a circumferential direction of the second substrate holder 2015 and the extension direction of each slit 2046 is oriented along the radial direction of the second substrate holder 2015.

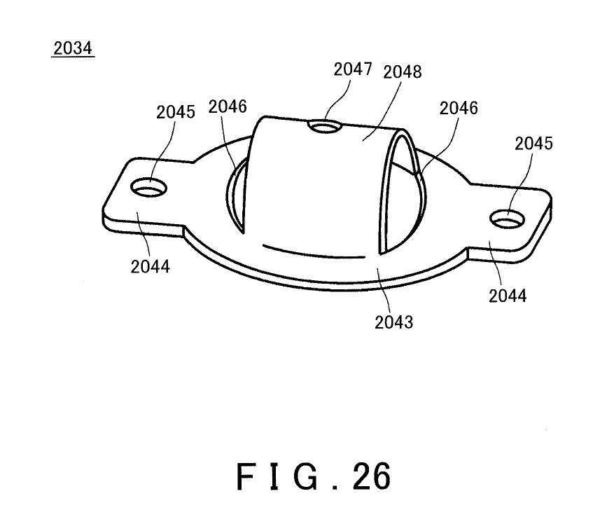

FIG. 26 is a perspective view schematically showing a state in which the flat spring 2034 is elastically deformed. Specifically, FIG. 10 shows a state in which the attracting element 2033 fixed to the flat spring 2034 is engaged with the magnet unit 2031 via attraction. It should be noted that the attracting element 2033 is not shown in FIG. 26.

In the flat spring 2034, as a result of the attracting element 2033 being attracted to the magnet unit 2031, the band-shaped portion 2048 rises upward such that that the through-hole 2047 becomes a peak, and the therefore two portions of the periphery of the circular portion 43 connected to the band-shaped portion 2048 are deformed to draw closer to each other. At this time, the shapes of the openings in the slits 2046 are deformed to allow for the above deformation.

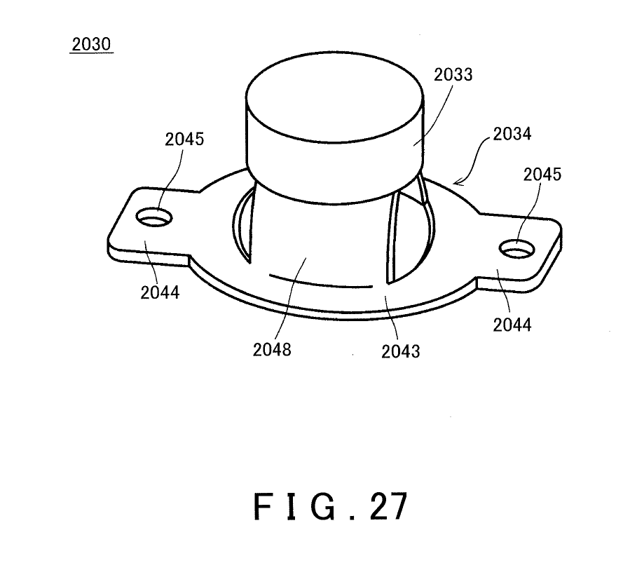

FIG. 27 is a perspective view including the attracting element 2033 when the flat spring 2034 of FIG. 26 is in the deformed state. The attracting element 2033 is fixed to the flat spring 2034 via the through-hole 2047, by a fastening member such as a screw. The attracting element 2033 is formed of a ferroelectric body. For example, the attracting element 2033 may be formed of carbon steel S25C.

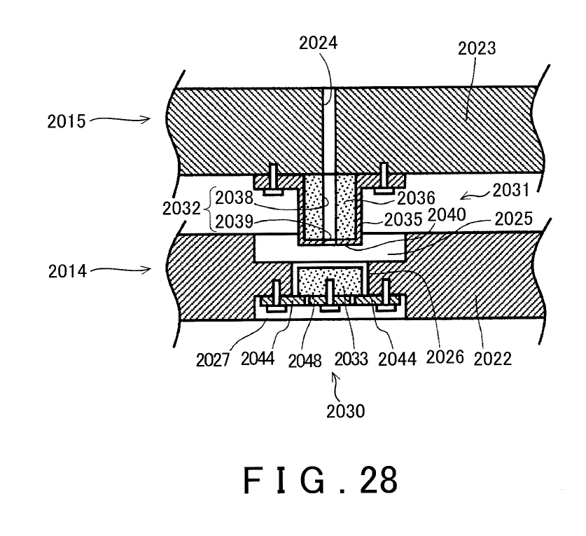

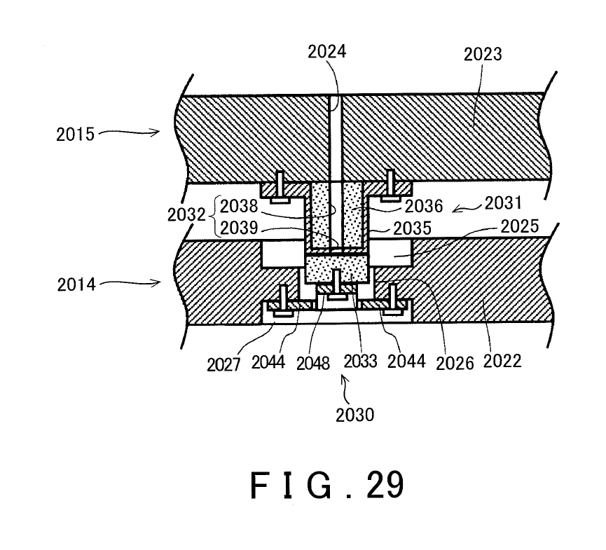

FIG. 28 is a cross-sectional view showing the coupling operation between the magnet unit 2031 and the attraction unit 2030. In particular, FIG. 28 shows a cross section over the line B-B in FIGS. 20 and 21. The first substrate 2016, the second substrate 2017, the push pin 2054, etc. are omitted from the drawing. FIG. 28 shows a state before the attracting element 2033 engages with the magnet unit 2031. FIG. 29 shows a state after the attracting element 2033 has engaged with the magnet unit 2031, using the same cross-sectional view as FIG. 28.

As shown in the drawings, the magnet unit 2031 is fixed to the surface of the second substrate holder 2015 by a screw. The counterface surface 2040 facing the attracting element 2033 is positioned below the first substrate 2016 holding surface of the first substrate holder 2014. In other words, the first substrate holder 2014 includes a recessed portion 2025 having a surface that is lower than the first substrate 2016 holding surface and corresponding to the region in which the attraction unit 2030 is provided. Specifically, the counterface surface 2040, which is the expected contact surface of the magnet unit 2031 expected to contact the attracting element 2033, is positioned within the recessed portion 2025 when the front surface of the first substrate 2016 and the front surface of the second substrate 2017 are in contact.

The recessed portion 2025 includes a through-hole 2026 that allows the attracting element 2033 to move up and down. The back surface of the first substrate holder 2014, which is the side opposite the surface holding the first substrate 2016, includes a recessed portion 2027 around the through-hole 2026, and the flat spring 2034 and a screw fixing the flat spring 2034 to the first substrate holder 2014 are arranged to be housed within the recessed portion.

As shown by the change from the state of FIG. 28 to the state of FIG. 29, the band-shaped portion 2048 to which the attracting element 2033 is affixed elastically deforms as a result of the attracting element 2033 being attracted by the magnet 2036. At this time, the attaching sections 2044 are fixed to the first substrate holder 2014, and therefore the flat spring 2034 biases the first substrate holder 2014 and the second substrate holder 2015 to draw closer to each other, by sandwiching the second substrate 2017 with the first substrate 2016.

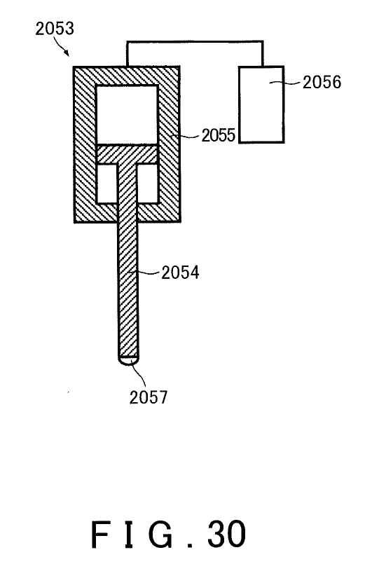

FIG. 30 is a vertical cross-sectional view schematically showing the engagement control unit 2053. A plurality of engagement control units 2053 are arranged on the second substrate holder 2015, corresponding to the magnet units 2031. The cylinder portion 2055 is connected to an air pump 2056 that adjusts the atmospheric pressure within the cylinder portion 2055. The control section causes the push pin 2054 to extend and retract by controlling the air pump 2056. More specifically, the control section causes the push pin 2054 to be at the stored position in which at least a portion of the push pin 2054 is within the cylinder portion 2055 or at the extended position in which the tip 2057 of the push pin 2054 presses the attracting element 2033. Accordingly, the pressing force exerted by the push pin 2054 on the attracting element 2033 is large enough to resist the elastic force of the flat spring 2034. The tip 2057 of the push pin 2054 is machined to be spherical, so as to achieve point contact with the attracting element 2033.

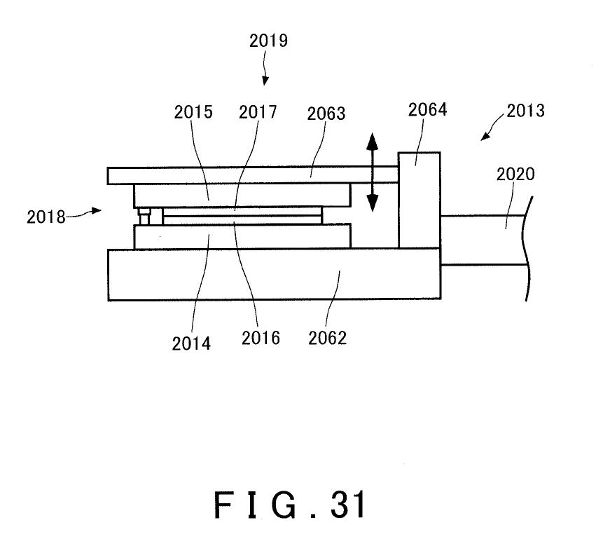

FIG. 31 is a side view schematically showing a state in which the transport apparatus 2013 grips the substrate holder pair 2018. The transport apparatus 2013 includes an arm portion 2020 and a gripping section 2019 that is connected to the arm portion 2020. The gripping section 2019 includes a support board 2062 that supports the substrate holder pair 2018 from below and a presser plate 2063 that presses the substrate holder pair 2018 from above. The support board 2062 includes a suction hole that fixes the substrate holder pair 2018 thereto using vacuum suction, and the substrate holder pair 2018 is fixed to the support board 2062 as a result of this suction.

The presser plate 2063 is provided on a support column 2064 formed on one end of the support board 2062, and can move back and forth in a direction to sandwich the substrate holder pair 2018. The presser plate 2063 exerts a pressing force on the substrate holder pair 2018 fixed to the support board 2062, such that the substrate holder pair 2018 can be sandwiched by the presser plate 2063 and the support board 2062. As a result of the arm portion 2020 moving while in this state, the transport apparatus 2013 transports the substrate holder pair 2018 from the alignment apparatus 2011 to the bonding apparatus 2012.

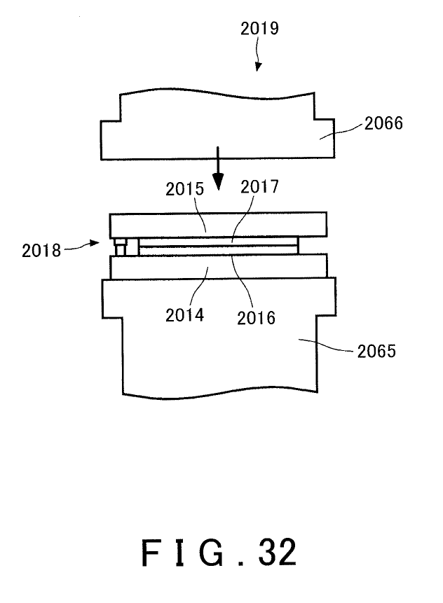

FIG. 32 is a side view schematically showing essential portions of the bonding apparatus 2012. The bonding apparatus 2012 includes a lower pressuring stage 2065 arranged below the first substrate holder 2014 and an upper pressuring stage 2066 arranged above the second substrate holder 2015. The upper pressuring stage 2066 can move toward the lower pressuring stage 2065, in order to apply pressure to the substrate holder pair 2018 together with the lower pressuring stage 2065. The lower pressuring stage 2065 and the upper pressuring stage 2066 each house a heater therein, and can therefore also apply heat to the substrate holder pair 2018 mounted thereon in addition to applying pressure. As a result of the pressure and heat being applied to the substrate holder pair 2018, the electrodes of the first substrate 2016 and the second substrate 2017 in contact with each other are fused together. As a result, the corresponding circuit regions 2021 of the first substrate 2016 and the second substrate 2017 are bonded together.

(First Modification of Second Embodiment)

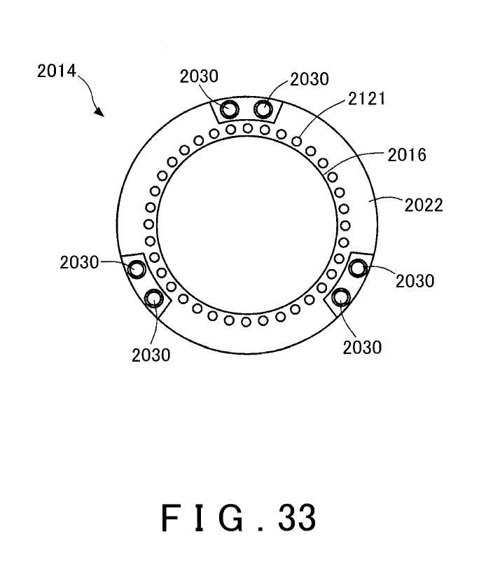

FIG. 33 is a planar view schematically showing a first substrate holder 2014 including a dust flow inhibiting mechanism, as a first modification of the second embodiment. The first substrate holder 2014 described in FIG. 20 includes first through-holes 2101 passing through the holder body 2022 in regions between the region holding the first substrate 2016 and the attraction units 2030. In contrast to this, the present modification includes, in addition to the first through-holes 2101, a plurality of through-holes that surround the region for holding the first substrate 2016. All of the through-holes together form an annular through-hole 2121 on the holder body 2022.

A plurality of through-holes corresponding to the annular through-hole 2121 of the first substrate holder 2014 are formed in a ring on the second substrate holder 2015. These through-holes are respectively connected to corresponding communicating tubes when the first stage 2051 or the second stage 2052 is exerting suction, in the same manner as the first communicating tubes 2111 connected to the first through-holes 2101 and the second communicating tubes 2112 connected to the second through-holes 2102. The through-holes connected to the communicating tubes suck in atmosphere near the openings thereof, as a result of the operation of the suction apparatus 2075. The substrate holder pair 2018 with this configuration can be expected to withdraw not only the dust generated by the bonding impact between the attraction unit 2030 and the magnet unit 2031, but also the dust that is scattered in the surrounding atmosphere, thereby preventing dust from entering between the first substrate 2016 and the second substrate 2017.

In the embodiment described above, suction is achieved through the through-holes by using communicating tubes that branch from the first suction piping 2071 or the second suction piping 2072. However, the at least one of the communicating tubes connected to a through-hole of the first substrate holder 2014 or the second substrate holder may be provided as a system that is separate from the first suction piping 2071 and the second suction piping 2072. If control is performed such that one intakes atmosphere while the other ejects atmosphere, an air curtain can be formed around the region for holding the substrate, and therefore dust from outside this region can be expected to be prevented from entering into this region.

(Second Modification of Second Embodiment)

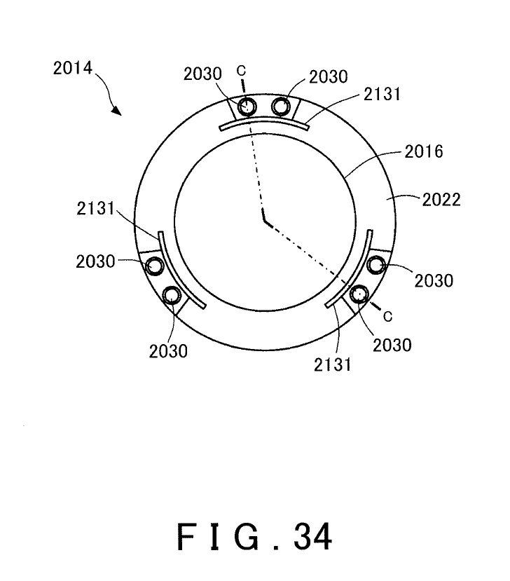

FIG. 34 is a planar view schematically showing a first substrate holder 2014 including a dust flow inhibiting mechanism, as a second modification of the second embodiment. The first substrate holder 2014 described in FIG. 20 includes first through-holes 2101 passing through the holder body 2022 in regions between the region holding the first substrate 2016 and the attraction units 2030. In contrast to this, the present modification includes, instead of the first through-holes 2101, first dust blocking walls 2131 formed by protrusions from the first substrate 2016 holding surface. In the example of FIG. 34, three arc-shaped first dust blocking walls 2131 are provided corresponding to the sets of attraction units 2030. The central angle of these arcs is set to be greater that the central angle formed by a set of attraction units 2030 in the circumferential direction.

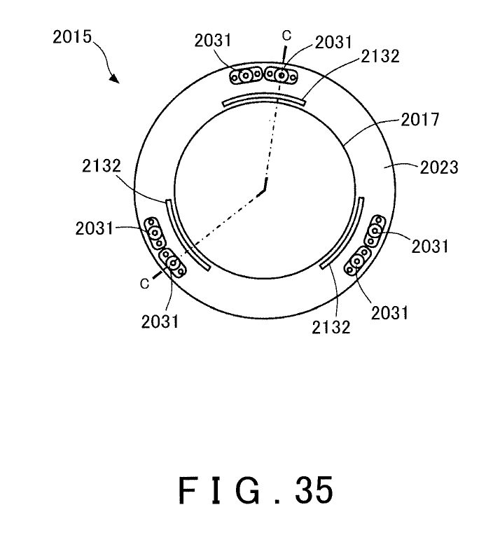

FIG. 35 is a planar view schematically showing a second substrate holder 2015 including a dust flow inhibiting mechanism according to the second modification. The second substrate holder 2015 described in FIG. 21 includes second through-holes 2102 passing through the holder body 2023 in regions between the region holding the second substrate 2017 and the magnet units 2031. In contrast to this, the present modification includes, instead of the second through-holes 2102, second dust blocking walls 2132 formed by protrusions from the second substrate 2017 holding surface. In the example of FIG. 35, three arc-shaped second dust blocking walls 2132 are provided corresponding to the sets of magnet units 2031. The central angle of these arcs is set to be greater that the central angle formed by a set of magnet units 2031 in the circumferential direction.

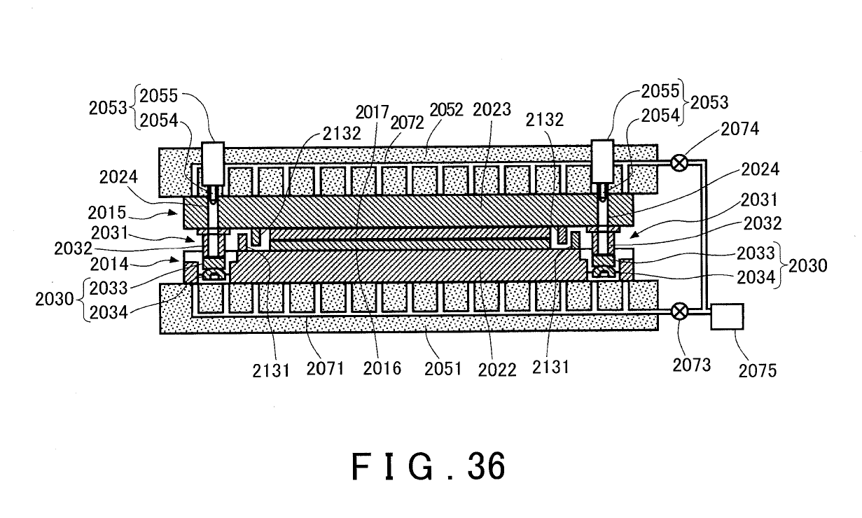

FIG. 36 is a cross-sectional view schematically showing a state immediately after formation of the substrate holder pair 2018 according to the second modification. Specifically, FIG. 36 is a cross-sectional view of a state in which the first substrate holder 2014 holding the first substrate 2016 is fixed to the first stage 2051 of the alignment apparatus 2011 by vacuum suction and the second substrate holder 2015 holding the second substrate 2017 is fixed to the second stage 2052 of the alignment apparatus 2011 by vacuum suction. In particular, the cross-sectional view is over the line C-C in FIGS. 34 and 35.

As shown in the drawings, the first dust blocking walls 2131 and the second dust blocking walls 2132 are in a nested form when the first substrate holder 2014 and the second substrate holder 2015 are stacked. The height of each first dust blocking wall 2131 is such that, when the first substrate holder 2014 and the second substrate holder 2015 are stacked, the first dust blocking wall 2131 extends beyond the contact surfaces of the first substrate 2016 and the second substrate 2017 toward the second substrate holder 2015 but does not contact the holding surface of the second substrate holder 2015 holding the second substrate 2017. The height of each second dust blocking wall 2132 is such that, when the first substrate holder 2014 and the second substrate holder 2015 are stacked, the second dust blocking wall 2132 extends beyond the contact surfaces of the first substrate 2016 and the second substrate 2017 toward the first substrate holder 2014 but does not contact the holding surface of the first substrate holder 2014 holding the first substrate 2016. Furthermore, the first dust blocking walls 2131 are formed further outward in a radial direction than the second dust blocking walls 2132, for example, such that the dust blocking walls do not interfere with each other. The inward or outward relationship in the radial direction may be reversed, and may be changed for each combination of an attraction unit 2030 and a magnet unit 2031.

With this configuration, even if dust is generated and scattered by the bonding impact between the attraction unit 2030 and the magnet unit 2031, the dust does not directly move toward the first substrate 2016 and the second substrate 2017. Specifically, the scattered dust can be expected to be prevented from passing beyond the first dust blocking walls 2131 and the second dust blocking walls 2132 prior to reaching the first substrate 2016 or the second substrate 2017, and therefore the dust does not stick to the first substrate 2016 or the second substrate 2017.

If the contact surfaces of the attraction unit 2030 and the magnet unit 2031 are positioned below the first substrate 2016 holding surface of the first substrate holder 2014 in the direction of gravity, the first dust blocking walls 2131 are preferably provided further outward than the second dust blocking walls 2132 in the radial direction. As a result, a path can be formed that makes it difficult for the dust to move toward the first substrate 2016 and the second substrate 2017.

The first dust blocking walls 2131 and the second dust blocking walls 2132 are not limited to having the arc shape described above. For example, each first dust blocking wall 2131 may include a radially shaped portion in addition to the arc shape, in a manner to surround the corresponding attraction unit 2030 group. In order to correspond to this shape, the second dust blocking walls 2132 may also each include a radially shaped portion in addition to the arc shape, in a manner to surround the corresponding magnet unit 2031 group. As another example, the first dust blocking wall 2131 may have a circular shape that surrounds the perimeter of the region for holding the first substrate 2016. In order to correspond to this shape, the second dust blocking wall 2132 may also have a circular shape that surrounds the perimeter of the region for holding the second substrate 2017. With the above shapes as well, dust generated by the bonding impact between the attraction unit 2030 and the magnet unit 2031 can be made to travel a complex path in order to each the first substrate 2016 and the second substrate 2017, in the same manner as when an arc shaped is used, and therefore the dust-blocking effect can be expected.

(Third Modification of Second Embodiment)

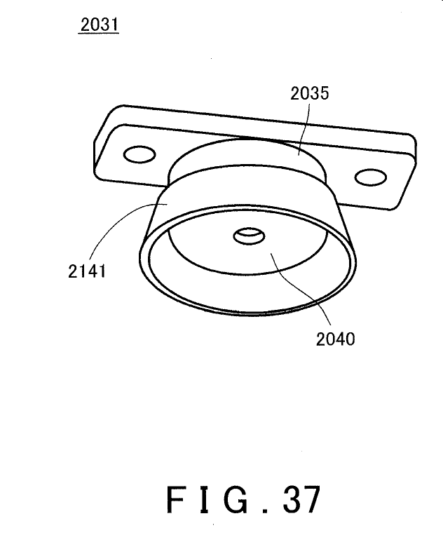

FIG. 37 is a perspective view schematically showing a magnet unit 2031 including a dust flow inhibiting mechanism, as a third modification of the second embodiment. The magnet unit according to the present modification further includes a shield 2141 in addition to the magnet unit 2031 described in FIG. 24. The shield 2141 is affixed by coupling with an outer cylindrical surface of the support section 2035, and is formed as a skirt that covers the counterface surface 2040 in a radial direction.

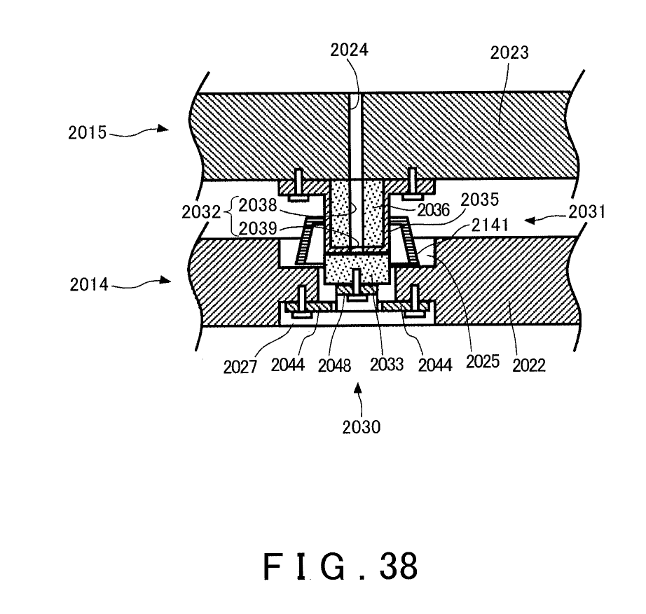

FIG. 38 is a cross-sectional view of a state in which the magnet unit 2031 with the shield 2141 attached thereto contacts the attraction unit 2030. The contact surfaces of the attraction unit 2030 and the magnet unit 2031 are positioned below the first substrate 2016 holding surface of the first substrate holder 2014, in the direction of gravity. Accordingly, when the first substrate holder 2014 and the second substrate holder 2015 are stacked, the recessed portion 2025 allows the shield 2141 to move below the first substrate 2016 holding surface of the first substrate holder 2014.

The magnet unit 2031 including the shield 2141 can trap the dust generated by the bonding impact of the attraction unit 2030 and the magnet unit 2031, within the shield 2141. Accordingly, the amount of dust expected to reach the first substrate 2016 and the second substrate 2017 is extremely small.

The shield 2141 may be freely attachable to the magnet unit 2031. In this case, maintenance can be performed easily by exchanging a shield 2141 that has become dirty due to the dust therein. As another example, the shield 2141 may be formed integrally with the support section 2035. In this case, the number of components is decreased, allowing for easier assembly.

In the manner described above, an electrode is embedded in the holder body 2023 of the second substrate holder 2015 to generate a potential difference between the second substrate holder 2015 and the second substrate 2017, thereby adhering the second substrate 2017 to the second substrate holder 2015. A charging section connected to the electrode may be provided on the shield 2141 to charge the shield 2141. When the shield 2141 is charged, the dust is expected to be attracted to the shield 2141, thereby increasing the dust trapping efficiency.

In the above modification, the shield is provided for the magnet unit 2031. However, the shield 2141 may instead be attached to the attracting element 2033. With this configuration as well, the scattering of the dust generated by the bonding impact between the attraction unit 2030 and the magnet unit 2031 can be restricted.

As described above, in each of the embodiments, the flow of dust toward the mounting regions for the first substrate 2016 and the second substrate 2017 can be inhibited when the attraction unit 2030 is engaged with the magnet unit 2031 in the substrate holder pair 2018. In other words, the flow of dust generated from both the attraction unit 2030 and the magnet unit 2031 due to the impact when these units are engaged can be inhibited. Furthermore, when the substrate holder pair 2018 is transported after the bonding, the flow dust between the first substrate holder 2014 and the second substrate holder 2015 toward the mounting regions of the first substrate 2016 and the second substrate 2017 is expected to be inhibited. Accordingly, circuit malfunctions due to dust in a device manufactured using the substrate holder pair 2018 are restricted, and therefore the device can be expected to have high quality. Furthermore, a high yield can be expected for the manufacturing of the device.

### Third Embodiment

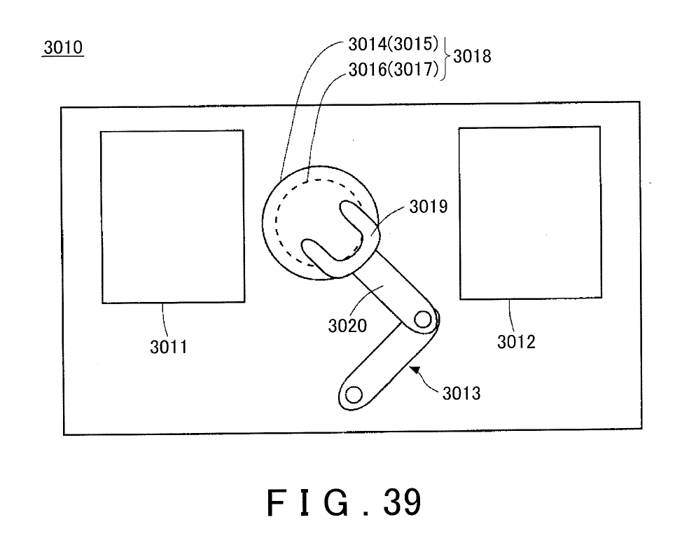

FIG. 39 schematically shows a substrate bonding apparatus 3010 according to a third embodiment. The substrate bonding apparatus 3010 includes an alignment apparatus 3011 that aligns a first substrate 3016, which is a semiconductor wafer, with a second substrate 3017, which is a semiconductor wafer to be layered on the first substrate 3016. The substrate bonding apparatus 3010 also includes a bonding apparatus 3012 that bonds together the first substrate 3016 and the second substrate 3017 aligned by the alignment apparatus 3011. The bonding apparatus 3012 performs permanent bonding of the first substrate 3016 and the second substrate 3017 by applying pressure or both pressure and heat thereto.

The first substrate 3016 is held by the first substrate holder 3014, and the second substrate 3017 is held by the second substrate holder 3015. In the alignment apparatus 3011, when the first substrate 3016 and the second substrate 3017 are aligned, the first substrate holder 3014 and the second substrate holder 3015 sandwich the first substrate 3016 and the second substrate 3017 to form these substrates integrally, thereby forming the substrate holder pair 3018. A detailed structure of the substrate holder pair 3018 is described further below.

The substrate bonding apparatus 3010 further includes a transport apparatus 3013 that transports the substrate holder pair 3018 integrated by the alignment apparatus 3011 to the bonding apparatus 3012. The transport apparatus 3013 can also transport a semiconductor wafer or a single substrate holder between apparatuses. The transport apparatus 3013 includes a gripping section 3019 that grips a gripping target such as the substrate holder pair 3018, and an arm portion 3020 that moves the gripping target to a prescribed position via rotating and extending/contracting movement.

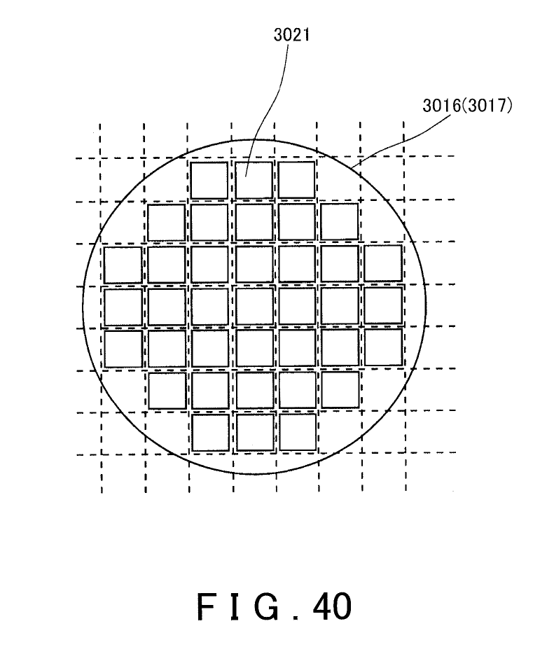

FIG. 40 is a planar view schematically showing a semiconductor wafer according to the present embodiment. The first substrate 3016 and the second substrate 3017, which are semiconductor wafers, are each formed of a circular thin board member made of single-crystal silicon, and each have one surface on which a plurality of circuit regions 3021 are formed. The circuit regions 3021 are partitioned into a matrix, and circuit elements such as transistors, resistors, and capacitors are formed therein. The circuit elements are formed using mainly lithography techniques such as thin film formation, etching, or impurity diffusion. Alignment marks are provided within each of the circuit regions 3021. The alignment marks are indicators used to align the substrates with each other. The plurality of alignment marks provided on each of the first substrate 3016 and the second substrate 3017 have their set coordinate values stored independently and managed in a memory. The semiconductor wafers to be layered may be semiconductor wafers that have already been layered with other semiconductor wafers. In this case, the previously layered circuit layers preferably undergo a thinning process to remove unnecessary thickness.

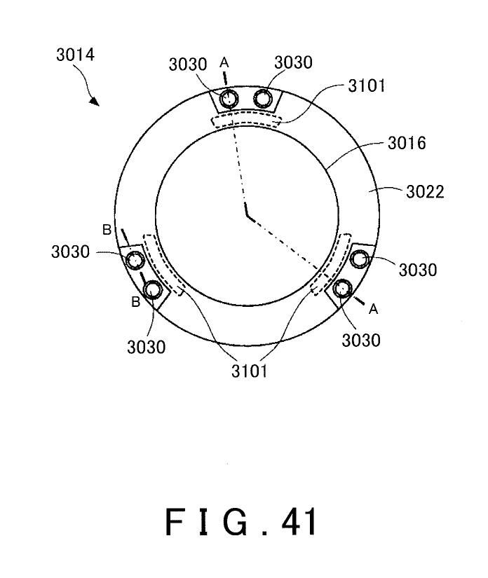

FIG. 41 is a planar view schematically showing the first substrate holder 3014 holding the first substrate 3016. The first substrate holder 3014 includes a holder body 3022 and an attraction unit 3030, which serves as an engaging section, and is shaped as a circular board with a diameter larger than that of the first substrate 3016. The holder body 3022 is formed integrally using a material with high rigidity such as ceramic or metal.

The holder body 3022 has a mounting region for holding and mounting the first substrate 3016 on the surface thereof. This mounting region is polished to be extremely flat. In FIG. 41, almost all of the region surrounded by the outer circumference of the first substrate 3016 corresponds to the mounting region. The holding of the first substrate 3016 is achieved by adhesion that uses electrostatic force. A detailed configuration is described further below. The adhesion surface of the first substrate 3016 is the surface opposite the surface on which the circuit regions 3021 are provided.

Each attraction unit 3030 includes a plurality of peripheral regions, which are arranged further outward than the first substrate 3016 mounting region of the on the surface that holds the first substrate 3016. In the example shown in the drawings, sets that each include two attraction units 3030 are arranged at intervals of 120 degrees to obtain a total of six attraction units 3030. A more detailed configuration is described further below.

The first substrate holder 3014 includes a first dust trapping region 3101, which traps dust, between the first substrate 3016 mounting region and each attraction unit 3030. In the drawings, a first dust trapping region 3101 is provided between each set of attraction units 3030 and the first substrate 3016 mounting region, but the number of first dust trapping regions 3101 may instead correspond to the number of attraction units 3030. The first dust trapping regions 3101 are regions that use electrostatic force to trap dust that is scattered from the attraction units 3030, in particular. A detailed configuration is described further below.

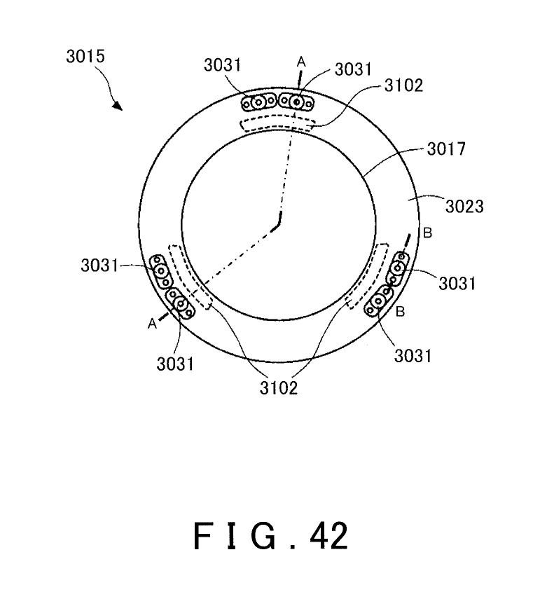

FIG. 42 is a planar view schematically showing the second substrate holder 3015 holding the second substrate 3017. The second substrate holder 3015 includes a holder body 3023 and a magnet unit 3031, which serves as an engaging section, and is shaped as a circular board with a diameter larger than that of the second substrate 3017. The holder body 3023 is formed integrally using a material with high rigidity such as ceramic or metal.

The holder body 3023 has a mounting region for holding and mounting the second substrate 3017 on the surface thereof. This mounting region is polished to be extremely flat. In FIG. 42, almost all of the region surrounded by the outer circumference of the second substrate 3017 corresponds to the mounting region. The holding of the second substrate 3017 is achieved by adhesion that uses electrostatic force. A detailed configuration is described further below. The adhesion surface of the second substrate 3017 is the surface opposite the surface on which the circuit regions 3021 are provided.

Each magnet unit 3031 includes a plurality of peripheral regions, which are arranged further outward than the second substrate 3017 mounting region on the surface that holds the second substrate 3017. In the example shown in the drawings, sets that each include two magnet units 3031 are arranged at intervals of 120 degrees to obtain a total of six magnet units 3031.

Each magnet unit 3031 is arranged to correspond to an attraction unit 3030 of the first substrate holder 3014. When the first substrate holder 3014 holding the first substrate 3016 and the second substrate holder 3015 holding the second substrate 3017 face each other and the attraction unit 3030 and magnet unit 3031 are made to operate, the first substrate 3016 and the second substrate 3017 can be sandwiched and fixed in a stacked state. This sandwiched and fixed state is the substrate holder pair 3018. Detailed descriptions of the configuration and adhesion operation are described further below.

The second substrate holder 3015 includes a second dust trapping region 3102, which traps dust, between the second substrate 3017 mounting region and each magnet unit 3031. In the drawings, a second dust trapping region 3102 is provided between each set of magnet units 3031 and the second substrate 3017 mounting region, but the number of second dust trapping regions 3102 may instead correspond to the number of magnet units 3031. The second dust trapping regions 3102 are regions that use electrostatic force to trap dust that is scattered from the magnet units 3031, in particular. A detailed configuration is described further below.

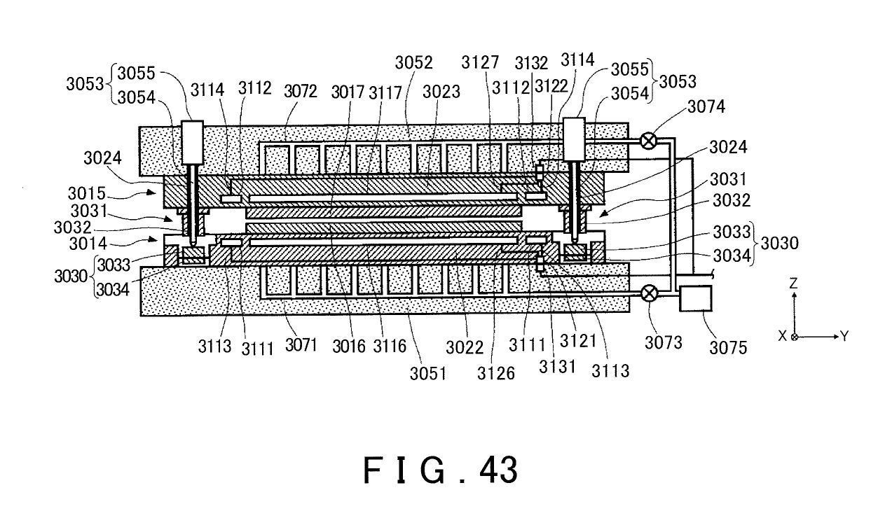

FIG. 43 is a cross-sectional view schematically showing a state immediately before the substrate holder pair 3018 is formed by the alignment apparatus 3011. Specifically, FIG. 43 is a cross-sectional view of a state in which the first substrate holder 3014 holding the first substrate 3016 is fixed to the first stage 3051 of the alignment apparatus 3011 by vacuum suction and the second substrate holder 3015 holding the second substrate 3017 is fixed to the second stage 3052 of the alignment apparatus 3011 by vacuum suction. In particular, the cross-sectional view is over the line A-A in FIGS. 41 and 42.

The first substrate holder 3014 is fixed to the front surface of the first stage 3051 by a vacuum suction force exerted by a suction apparatus 3075 via a first suction piping 3071 passing through the first stage 3051 to reach the front surface thereof. The first suction piping 3071 includes a plurality of branches reaching the front surface of the first stage 3051, and exerts uniform suction over a wide region on the back surface of the first substrate holder 3014. The suction force of the suction apparatus 3075 is adjusted by a first valve 3073, in order to control attachment and detachment of the first substrate holder 14.

Similarly, the second substrate holder 3015 is fixed to the front surface of the second stage 3052 by a vacuum suction force exerted by a suction apparatus 3075 via a second suction piping 3072 passing through the second stage 3052 to reach the front surface thereof. The second suction piping 3072 includes a plurality of branches reaching the front surface of the second stage 3052, and exerts uniform suction over a wide region on the back surface of the second substrate holder 3015. The suction force of the suction apparatus 3075 is adjusted by a second valve 3074, in order to control attachment and detachment of the second substrate holder 15.

The first stage 3051 can move the first substrate 3016 relative to the second substrate 3017, in a Z-axis direction that is the layering direction and X-axis and Y-axis directions that are each orthogonal to the Z-axis. The alignment apparatus 3011 aligns the first substrate 3016 and the second substrate 3017, by using a first microscope arranged on the alignment apparatus 3011 in a manner to be able to observe the first substrate 3016 and a second microscope arranged on the alignment apparatus 3011 in a manner to be able to observe the second substrate 3017.

More specifically, each microscope is used to capture images of the alignment marks on each substrate serving as an observation target, and precise positions of the alignment marks are detected by performing image processing on the captured image data. The positional skew amount between corresponding alignment marks is then calculated and the first stage 3051 is moved according to this positional skew amount, thereby aligning the first substrate 3016 and the second substrate 3017. In this way, each circuit region 3021 of the first substrate 3016 faces a corresponding circuit region 3021 of the second substrate 3017. The positional skew amount calculation may be performed using a global alignment technique, for example, in which the positional skew amount is statistically determined to have a minimum value when the plurality of alignment marks of the first substrate 3016 overlap the plurality of alignment marks of the second substrate 3017.

When aligning the first substrate 3016 with the second substrate 3017, i.e. when moving the first stage 3051 in the XY-plane, a small gap is maintained between the first substrate 3016 and the second substrate 3017 such that the substrates do not contact each other. The second stage 3052 includes a plurality of engagement control units 3053, such that the attraction units 3030 do not engage with the magnet units 3031 when in this state.

Each engagement control unit 3053 is mainly formed from a push pin 3054, which is a member shaped as a pillar, and a cylinder portion 3055 that drives the push pin 3054. When at an extended position, the push pin 3054 passes through a holder insertion hole 3024 that is provided in the second substrate holder 3015 and a magnet insertion hole 3032 provided in the magnet unit 3031 arranged to be aligned with the holder insertion hole 3024, such that the tip of the push pin 3054 protrudes beyond the magnet insertion hole 3032. When at a storage position, a portion of the push pin 3054 is stored within the cylinder portion 3055, and is withdrawn from the insertion holes. In other words, the push pin 3054 moves back and forth in the Z-axis direction within the insertion holes, according to the drive of the cylinder portion 3055.

When the first substrate 3016 and the second substrate 3017 are to be moved relative to each other in the XY-plane, such as shown in FIG. 43, the push pins 3054 are held at the extended position in contact with the top surfaces of the attraction units 3030, thereby preventing the attraction units 3030 from engaging with the magnet units 3031. In other words, the attraction units 3030 are formed by attracting elements 3033 and flat springs 3034 fixed to the attracting elements 3033, but the push pins 3054 press on the attracting elements 3033 from above to restrict the elastic deformation of the flat springs 3034, such that the attracting elements 3033 do not engage with the magnet units 3031 as a result of the elastic deformation of the flat springs 3034.

The alignment of the first substrate 3016 and the second substrate 3017 by the alignment apparatus 3011 is performed at a final fine adjustment stage in which the movement amount is such that the tips of the push pins 3054 slide along the top surfaces of the attraction units 3030. At other stages, such as an observation stage in which the alignment marks are observed by the microscopes, the first substrate 3016 and the second substrate 3017 are separated from each other by a large amount in the X-, Y-, and Z-axis directions, and therefore the attraction units 3030 do not unexpectedly engage with the magnet units 3031. Accordingly, the push pins 3054 are held at the extended position when the magnetic force of the magnet units 3031 is exerted on the attraction units 3030 and engaging therebetween is to be prevented, and are held at the stored position at all other times.

A first substrate electrode 3116 is embedded in the holder body 3022 of the first substrate holder 3014, to correspond to the first substrate 3016 mounting region. The first substrate electrode 3116 is connected to a first voltage application terminal 3121 by a first substrate wiring 3126. The first voltage supply terminal 3131 is embedded in the first stage 3051 at a position corresponding to the first voltage application terminal 3121, and when the first substrate holder 3014 is fixed to the first stage 3051, the first voltage application terminal 3121 is connected to the first voltage supply terminal 3131. The first voltage supply terminal 3131 is supplied with voltage from an external power supply, via a conductive line embedded through the first stage 3051. The voltage supply from the external power supply to the first voltage supply terminal 3131 is controlled by a control section of the alignment apparatus 3011. With this configuration, a potential difference is generated between the first substrate 3016 and the first substrate holder 3014, and therefore the first substrate 3016 is adhered to the mounting region of the first substrate holder 3014 by electrostatic force, and the bias toward the first substrate holder 3014 is maintained.

A second substrate electrode 3117 is embedded in the holder body 3023 of the second substrate holder 3015, to correspond to the second substrate 3017 mounting region. The second substrate electrode 3117 is connected to a second voltage application terminal 3122 by a second substrate wiring 3127. The second voltage supply terminal 3132 is embedded in the second stage 3052 at a position corresponding to the second voltage application terminal 3122, and when the second substrate holder 3015 is fixed to the second stage 3052, the second voltage application terminal 3122 is connected to the second voltage supply terminal 3132. The second voltage supply terminal 3132 is supplied with voltage from an external power supply, via a conductive line embedded through the second stage 3052. The voltage supply from the external power supply to the second voltage supply terminal 3132 is controlled by a control section of the alignment apparatus 3011. With this configuration, a potential difference is generated between the second substrate 3017 and the second substrate holder 3015, and therefore the second substrate 3017 is adhered to the mounting region of the second substrate holder 3015 by electrostatic force, and the bias toward the second substrate holder 3015 is maintained.

A first dust trapping electrode 3111 is also embedded in the holder body 3022 of the first substrate holder 3014, corresponding to the first dust trapping region 3101. The first dust trapping electrode 3111 is connected to the first voltage application terminal 3121 by a first dust wiring 3113. Accordingly, when the first substrate holder 3014 is fixed to the first stage 3051, the first dust trapping electrode 3111 is also supplied with voltage. With this configuration, when voltage is supplied to the first dust trapping electrode 3111, the first dust trapping region 3101 becomes charged. The floating dust often has a negative charge, and therefore when the first dust trapping region 3101 is supplied with voltage from the first dust trapping electrode 3111 to have a positive charge, this dust is drawn in and adhered to the first dust trapping region 3101.

In the manner described above, the voltage supply to the first substrate electrode 3116 and the voltage supply to the first dust trapping electrode 3111 are supplied via a common first voltage application terminal 3121. However, the line resistances of the first substrate wiring 3126 and the first dust wiring 3113 may be set to be different from each other, in order to create a difference between the electrostatic attractive force per unit area in the first substrate 3016 mounting region and the electrostatic attractive force per unit area in the first dust trapping region 3101. Specifically, in order to exert a stronger attractive force on the floating dust, the electrostatic attractive force per unit area in the first dust trapping region 3101 may be set to be greater than the electrostatic attractive force per unit area in the first substrate 3016 mounting region.

The external contours of the first dust trapping electrode 3111 and the first substrate electrode 3116 and the position of the embedding in the holder body 3022 are determined such that the forms of the first dust trapping electrode 3111 and the first substrate electrode 3116, as projected in a direction in which the first substrate 3016 is mounted, do not overlap each other. As a result, the first substrate 3016 mounting region and the first dust trapping region 3101 can be distanced from each other, thereby avoiding movement of the trapped dust toward the first substrate 3016.

A second dust trapping electrode 3112 is also embedded in the holder body 3023 of the second substrate holder 3015, corresponding to the second dust trapping region 3102. The second dust trapping electrode 3112 is connected to the second voltage application terminal 3122 by a second dust wiring 3114. Accordingly, when the second substrate holder 3015 is fixed to the second stage 3052, the second dust trapping electrode 3112 is also supplied with voltage. With this configuration, when voltage is supplied to the second dust trapping electrode 3112, the second dust trapping region 3102 becomes charged. In the same manner as the first dust trapping region 3101, if the second dust trapping region 3102 is supplied with voltage from the second dust trapping electrode 3112 to have a positive charge, dust can be drawn in and adhered to the second dust trapping region 3102.

In the same manner as the first substrate holder 3014, the electrostatic attractive force per unit area in the second dust trapping region 3102 is preferably set to be greater than the electrostatic attractive force per unit area in the second substrate 3017 mounting region. Furthermore, the external contours of the second dust trapping electrode 3112 and the second substrate electrode 3117 and the position of the embedding in the holder body 3023 are determined such that the forms of the second dust trapping electrode 3112 and the second substrate electrode 3117, as projected in a direction in which the second substrate 3017 is mounted, do not overlap each other.

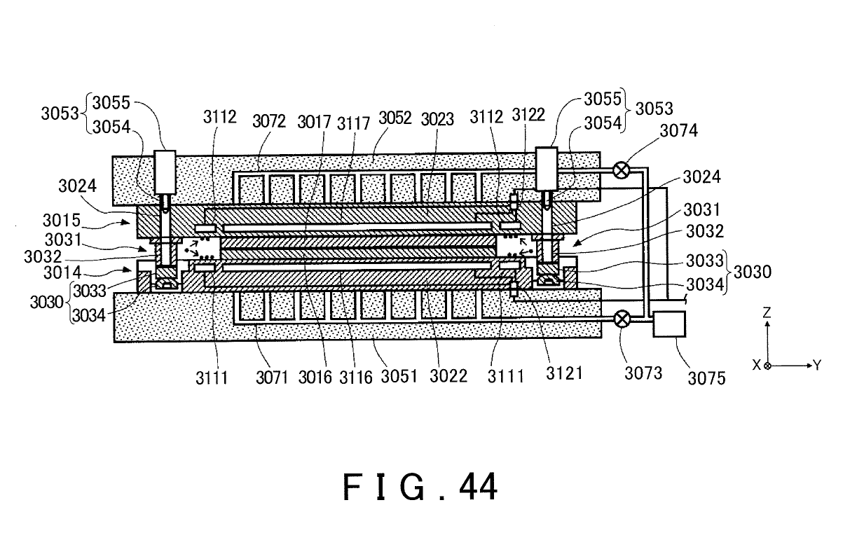

FIG. 44 is a cross-sectional view schematically showing a state immediately after formation of the substrate holder pair 3018 by the alignment apparatus 3011. Specifically, FIG. 44 shows a state in which the first stage 3051 has been driven in the Z-axis direction from the state shown in FIG. 43, such that the surface of the first substrate 3016 contacts the surface of the second substrate 3017, the push pins 3054 are held at the storage position, and the attraction units 3030 and magnet units 3031 are engaged.

During the process of transitioning from the state of FIG. 43 to the state of FIG. 44, the first substrate 3016 and the second substrate 3017 are aligned, and the magnet units 3031, which are engaging members, are engaged with the attraction units 3030, which are engagement receiving members. The first substrate holder 3014 and the second substrate holder 3015 are then formed integrally, thereby forming the substrate holder pair 3018 as the substrate holder system.

When the flat springs 3034 deform and the attraction units 3030 engage with the magnet units 3031, the engagement of the attracting elements 3033 of the attraction units 3030 with the magnet units 3031 is accompanied by a small impact. At this time, dust can be generated and scattered by the impact of the engagement of the attraction units 3030 and the magnet units 3031. When this dust becomes stuck between the first substrate 3016 and the second substrate 3017 and in nearby regions, the non-uniform heating and pressurization and a decrease in bonding strength can occur in the bonding process performed later by the bonding apparatus 3012. Furthermore, the completed semiconductor device can experience defects in circuit operation due to the dust therein.

In order to solve such problems, in the present embodiment, for at least some time from when the attraction units 3030 contact the magnet units 3031, the control section supplies voltage to the first dust trapping electrode 3111 and the second dust trapping electrode 3112 to trap scattered dust in the first dust trapping region 3101 and the second dust trapping region 3102. By adopting this configuration, the generated dust is expected to be withdrawn prior to entering between the first substrate 3016 and the second substrate 3017.

After the substrate holder pair 3018 is formed, the substrate holder pair 3018 is released from the vacuum suction of the second stage 3052, lifted up by the first stage 3051, and transported to the bonding apparatus 3012 by the transport apparatus 3013. The transportation mechanism of the transport apparatus 3013 and the bonding process of the bonding apparatus 3012 are described further below.

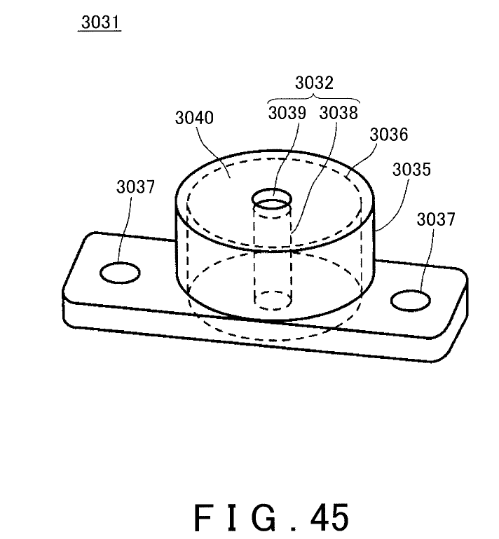

The following describes a configuration of the magnet unit 3031. FIG. 45 is a perspective view schematically showing the magnet unit 3031. The magnet unit 3031 includes a magnet 3036 and a support section 3035 housing the magnet 3036.

The support section 3035 includes a housing portion shaped as a circular cylinder that houses the magnet 3036, and a threaded hole 3037 through which passes a screw for fixing the support section 3035 to the second substrate holder 3015. The support section 3035 is formed by carbon steel S25C, for example. The support section 3035 has a counterface surface 3040 that faces the attracting element 3033. The magnet 3036 is a permanent magnet shaped as a circular pillar that can be inserted into the housing portion of the support section 3035, and may have a magnetic force of approximately 8 N, for example. The central axis of the magnet 3036 is provided with an insertion hole 3038 into which is inserted a push pin 3054, and an insertion hole 3039 in series with the insertion hole 3038 and into which the support section 3035 is inserted. The magnet insertion hole 3032 is formed by these two insertion holes.

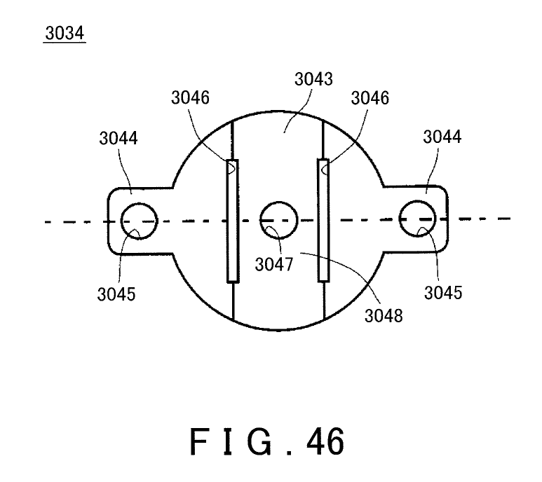

The following describes a configuration of an attraction unit 3030. FIG. 46 is a planar view schematically showing a flat spring 3034 of the attraction unit 3030. The flat spring 3034 is an elastic member having elasticity in a direction orthogonal to the holding surface of the second substrate holder 3015 that holds the second substrate 3017, and may be formed of a high-strength precipitation-hardening stainless steel, such as SUS 631. The flat spring 3034 is formed by a central circular portion 43 and attaching sections 3044 protruding therefrom as ears. The circular portion 43 has a diameter of 22 mm and a thickness of 0.1 mm.

A pair of slits 3046 that extend in the same direction as each other are arranged in the circular portion 43 with an interval therebetween in a direction orthogonal to the extension direction. Each slit 3046 is the same distance from the center of the circular portion 43. The two slits 3046 form a band-shaped portion 3048 in the central region of the circular portion 43. A through-hole 3047 that fixes the attracting element 3033 is formed in the band-shaped portion 3048 at the center of the circular portion 43. Similarly, each attaching section 3044 includes a threaded hole 3045 through which passes a screw for fixing the flat spring 3034 to the second substrate holder 3015. The flat spring 3034 is arranged in a peripheral region of the holder body 3023, such that the two threaded holes 3045 are oriented along a circumferential direction of the second substrate holder 3015 and the extension direction of each slit 3046 is oriented along the radial direction of the second substrate holder 3015.

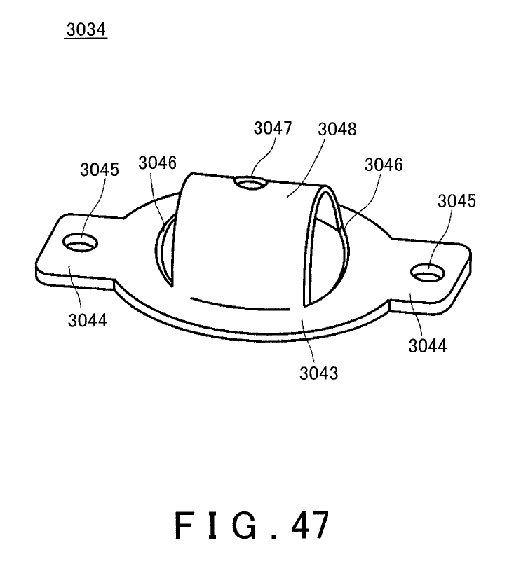

FIG. 47 is a perspective view schematically showing a state in which the flat spring 3034 is elastically deformed. Specifically, FIG. 47 shows a state in which the attracting element 3033 fixed to the flat spring 3034 is engaged with the magnet unit 3031 via attraction. It should be noted that the attracting element 3033 is not shown in FIG. 47.

In the flat spring 3034, as a result of the attracting element 3033 being attracted to the magnet unit 3031, the band-shaped portion 3048 rises upward such that that the through-hole 3047 becomes a peak, and the therefore two portions of the periphery of the circular portion 43 connected to the band-shaped portion 3048 are deformed to draw closer to each other. At this time, the shapes of the openings in the slits 3046 are deformed to allow for the above deformation.

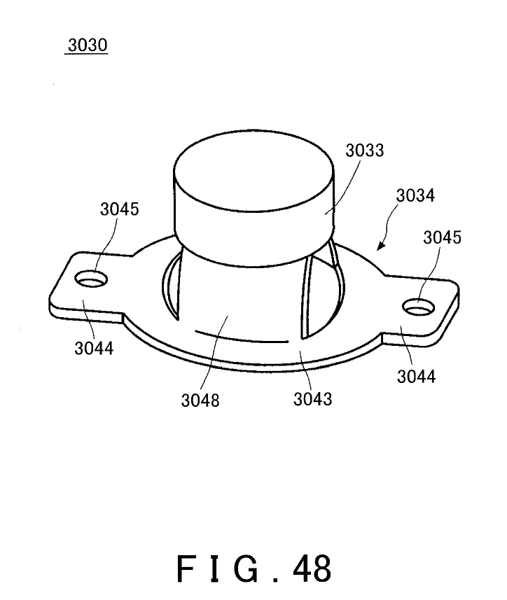

FIG. 48 is a perspective view including the attracting element 3033 when the flat spring 3034 of FIG. 47 is in the deformed state. The attracting element 3033 is fixed to the flat spring 3034 via the through-hole 3047, by a fastening member such as a screw. The attracting element 3033 is formed by a ferromagnetic body. For example, the attracting element 3033 may be formed of carbon steel S25C.

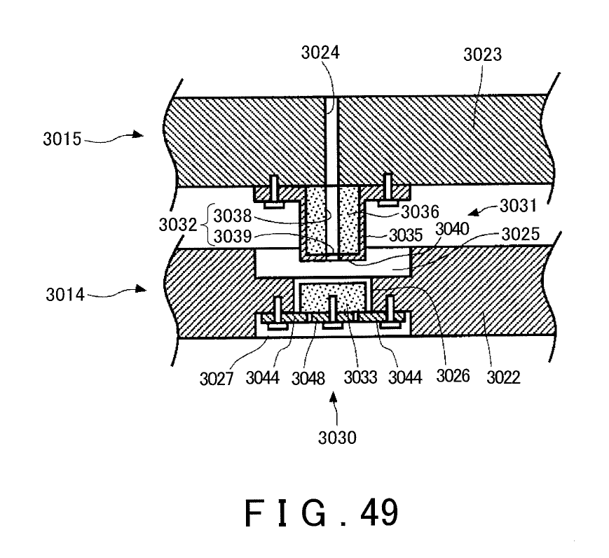

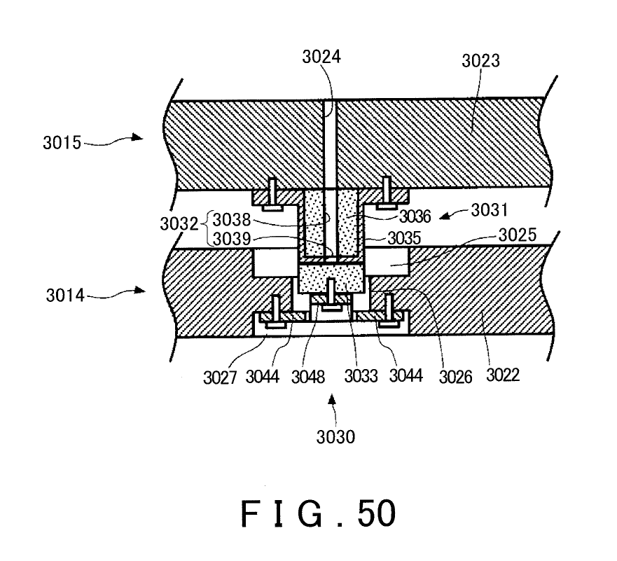

FIG. 49 is a cross-sectional view showing the coupling operation between the magnet unit 3031 and the attraction unit 3030. In particular, FIG. 49 shows a cross section over the line B-B in FIGS. 41 and 42. The first substrate 3016, the second substrate 3017, the push pin 3054, etc. are omitted from the drawing. FIG. 49 shows a state before the attracting element 3033 engages with the magnet unit 3031. FIG. 50 shows a state after the attracting element 3033 has engaged with the magnet unit 3031, using the same cross-sectional view as FIG. 49.

As shown in the drawings, the magnet unit 3031 is fixed to the surface of the second substrate holder 3015 by a screw. The counterface surface 3040 facing the attracting element 3033 is positioned below the first substrate 3016 holding surface of the first substrate holder 3014. In other words, the first substrate holder 3014 includes a recessed portion 3025 having a surface that is lower than the first substrate 3016 holding surface and corresponding to the region in which the attraction unit 3030 is provided. Specifically, the counterface surface 3040, which is the expected contact surface of the magnet unit 3031 expected to contact the attracting element 3033, is positioned within the recessed portion 3025 when the front surface of the first substrate 3016 and the front surface of the second substrate 3017 are in contact.

The recessed portion 3025 includes a through-hole 3026 that allows the attracting element 3033 to move up and down. The back surface of the first substrate holder 3014, which is the side opposite the surface holding the first substrate 3016, includes a recessed portion 3027 around the through-hole 3026, and the flat spring 3034 and a screw fixing the flat spring 3034 to the first substrate holder 3014 are arranged to be housed within the recessed portion.

As shown by the change from the state of FIG. 49 to the state of FIG. 50, the band-shaped portion 3048 to which the attracting element 3033 is affixed elastically deforms as a result of the attracting element 3033 being attracted by the magnet 3036. At this time, the attaching sections 3044 are fixed to the first substrate holder 3014, and therefore the flat spring 3034 biases the first substrate holder 3014 and the second substrate holder 3015 to draw closer to each other, by sandwiching the second substrate 3017 with the first substrate 3016.

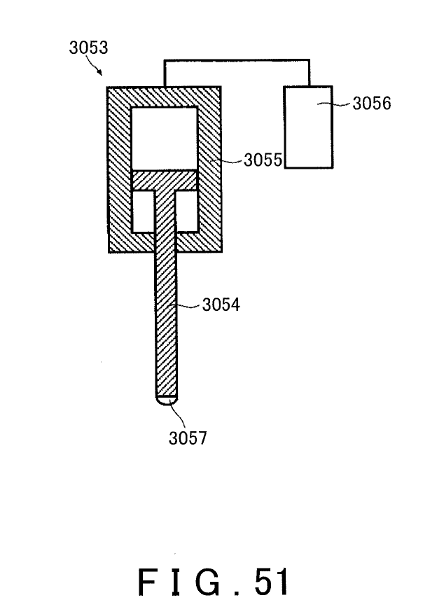

FIG. 51 is a cross-sectional view schematically showing the engagement control unit 3053. A plurality of engagement control units 3053 are arranged on the second substrate holder 3015, corresponding to the magnet units 3031. The cylinder portion 3055 is connected to an air pump 3056 that adjusts the atmospheric pressure within the cylinder portion 3055. The control section causes the push pin 3054 to extend and retract by controlling the air pump 3056. More specifically, the control section causes the push pin 3054 to be at the stored position in which at least a portion of the push pin 3054 is within the cylinder portion 3055 or at the extended position in which the tip 3057 of the push pin 3054 presses the attracting element 3033. Accordingly, the pressing force exerted by the push pin 3054 on the attracting element 3033 is large enough to resist the elastic force of the flat spring 3034. The tip 3057 of the push pin 3054 is machined to have a spherical shape, in order to achieve point contact with the attracting element 3033.

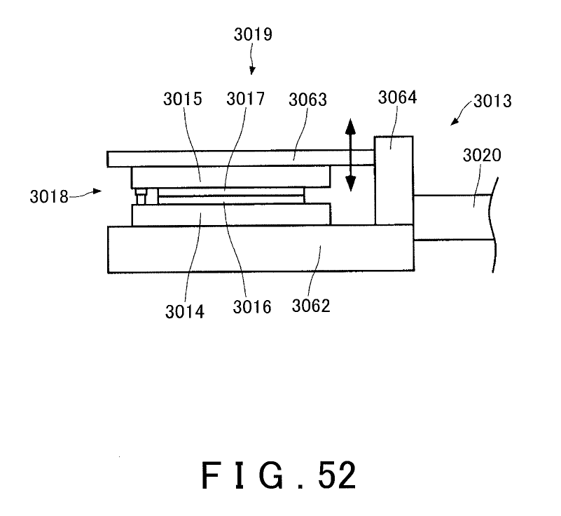

FIG. 52 is a side view schematically showing a state in which the transport apparatus 3013 grips the substrate holder pair 3018. The transport apparatus 3013 includes an arm portion 3020 and a gripping section 3019 that is connected to the arm portion 3020. The gripping section 3019 includes a support board 3062 that supports the substrate holder pair 3018 from below and a presser plate 3063 that presses the substrate holder pair 3018 from above. The support board 3062 includes a suction hole that fixes the substrate holder pair 3018 thereto using vacuum suction, and the substrate holder pair 3018 is fixed to the support board 3062 as a result of this suction.

The presser plate 3063 is provided on a support column 3064 formed on one end of the support board 3062, and can move back and forth in a direction to sandwich the substrate holder pair 3018. The presser plate 3063 exerts a pressing force on the substrate holder pair 3018 fixed to the support board 3062, such that the substrate holder pair 3018 can be sandwiched by the presser plate 3063 and the support board 3062. As a result of the arm portion 3020 moving while in this state, the transport apparatus 3013 transports the substrate holder pair 3018 from the alignment apparatus 3011 to the bonding apparatus 3012. The transport apparatus 3013 can supply voltage to the first voltage application terminal 3121 and the second voltage application terminal 3122 during transport as well. In this way, the first substrate 3016 and the second substrate 3017 can be adhered the substrate holders using electrostatic force, and there is no worry that the substrates and substrate holders will shift relative to each other during transport.

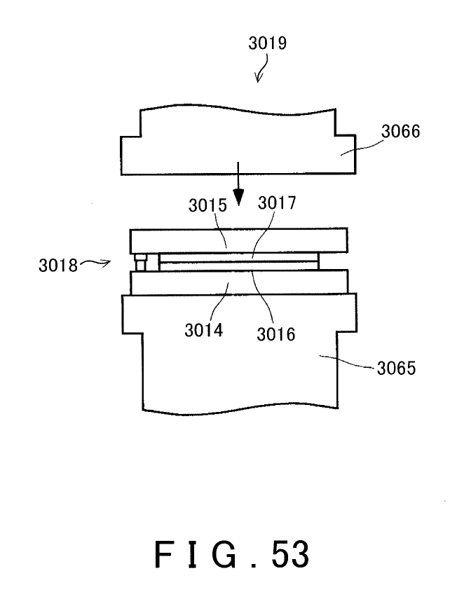

FIG. 53 is a side view schematically showing essential portions of the bonding apparatus 3012. The bonding apparatus 3012 includes a lower pressuring stage 3065 arranged below the first substrate holder 3014 and an upper pressuring stage 3066 arranged above the second substrate holder 3015. The upper pressuring stage 3066 can move toward the lower pressuring stage 3065, in order to apply pressure to the substrate holder pair 3018 together with the lower pressuring stage 3065. The lower pressuring stage 3065 and the upper pressuring stage 3066 each house a heater therein, and can therefore also apply heat to the substrate holder pair 3018 mounted thereon in addition to applying pressure. As a result of the pressure and heat being applied to the substrate holder pair 3018, the electrodes of the first substrate 3016 and the second substrate 3017 in contact with each other are fused together. As a result, the corresponding circuit regions 3021 of the first substrate 3016 and the second substrate 3017 are bonded together.

(First Modification of Third Embodiment)

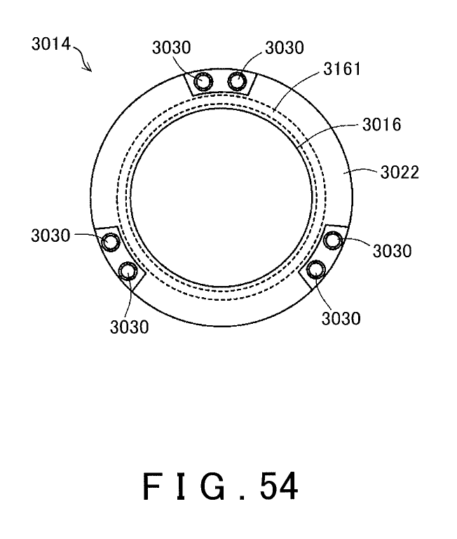

FIG. 54 is a planar view schematically showing a first substrate holder 3014 including a dust trapping region, as a first modification of the third embodiment. The first substrate holder 3014 described using FIG. 41 includes a first dust trapping region 3101 that traps dust between the first substrate 3016 mounting region and each attraction unit 3030. In contrast to this, the present modification includes a dust trapping region 3161 formed as a ring that surrounds the first substrate 3016 mounting region and formed by connecting the first dust trapping regions 3101. A dust trapping electrode is also formed as a ring and embedded in the holder body 3022 to correspond to the dust trapping region 3161

A ring-shaped dust trapping region is also formed in the second substrate holder 3015, corresponding to the dust trapping region 3161 of the first substrate holder 3014. The substrate holder pair 3018 with this configuration can be expected to withdraw not only the dust generated by the bonding impact between the attraction unit 3030 and the magnet unit 3031, but also the dust that is scattered in the surrounding atmosphere, thereby preventing dust from entering between the first substrate 3016 and the second substrate 3017.

(Second Modification of Third Embodiment)

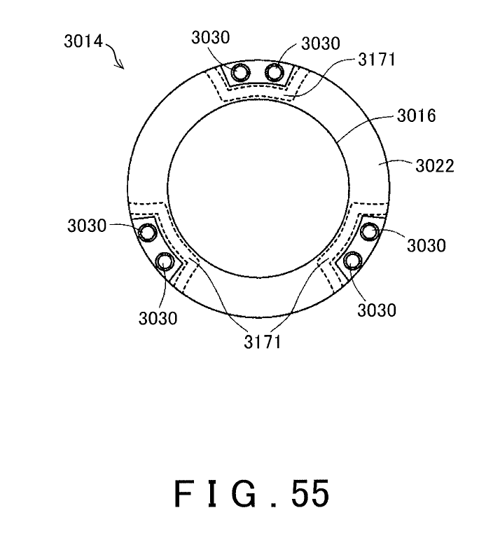

FIG. 55 is a planar view schematically showing a first substrate holder 3014 including a dust trapping region, as a second modification of the third embodiment. The first substrate holder 3014 described using FIG. 41 includes an arc-shaped first dust trapping region 3101 that traps dust between the first substrate 3016 mounting region and each attraction unit 3030. In contrast to this, the present modification includes, in addition to these arc-shaped regions, a dust trapping region 3171 formed as a ring that surrounds the attraction units 3030. A dust trapping electrode is also formed and embedded in the holder body 3022 to surround the attraction units 3030, and corresponds to the dust trapping region 3171.

A ring-shaped dust trapping region surrounding the magnet units 3031 is also formed in the second substrate holder 3015, corresponding to the dust trapping region 3161 of the first substrate holder 3014. The substrate holder pair 3018 with this configuration can more reliably trap the dust generated by the bonding impact between the attraction units 3030 and the magnet units 3031.

(Third Modification of Third Embodiment)

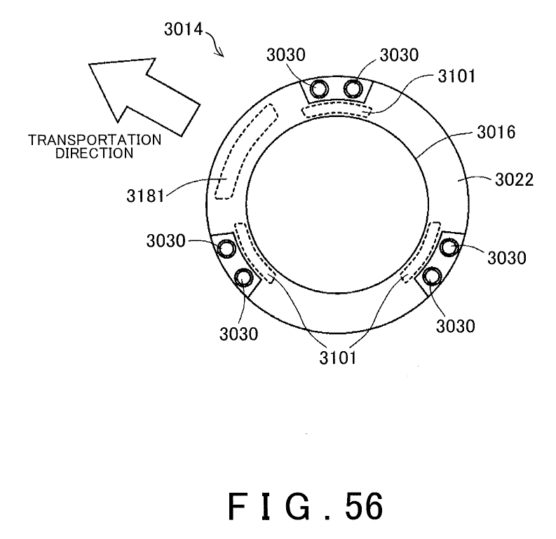

FIG. 56 is a planar view schematically showing a first substrate holder 3014 including a dust trapping region, as a third modification of the third embodiment. The first substrate holder 3014 described using FIG. 41 includes a first dust trapping region 3101 that traps dust between the first substrate 3016 mounting region and each attraction unit 3030. In contrast to this, the present modification includes a mid-transportation dust trapping region 3181 in addition to the first dust trapping regions 3101. A mid-transport dust trapping electrode is embedded in the holder body 3022 to correspond to the mid-transportation dust trapping region 3181.

When the first substrate holder 3014 is transported by the transport apparatus 3013 or other apparatuses such as a slider mechanism, the bias of the first substrate holder 3014 in the transportation direction is often determined in advance. Therefore, the mid-transportation dust trapping region 3181 is provided in a region on the transportation direction side of the first substrate holder 3014 to prevent dust from sticking to the first substrate 3016, by trapping dust that flies in from the transportation direction. When the first substrate holder 3014 is transported by the transport apparatus 3013 or another apparatus such as a slider mechanism, the bias of the first substrate holder 3014 on the transport apparatus 3013 may be controlled such that the mid-transportation dust trapping region 3181 is on the transportation direction side.

A mid-transportation dust trapping region 3181 is also provided on the second substrate holder 3015 to correspond to the mid-transportation dust trapping region 3181 of the first substrate holder 3014. The substrate holder pair 3018 with this configuration can be expected to withdraw not only the dust generated by the bonding impact between the attraction unit 3030 and the magnet unit 3031, but also the dust that is scattered in the surrounding atmosphere, thereby preventing dust from entering between the first substrate 3016 and the second substrate 3017.

The objective of the first dust trapping region 3101 and the second dust trapping region 3102 is to trap the dust generated by the bonding impact between the attraction units 3030 and the magnet units 3031, and the objective of the mid-transportation dust trapping region 3181 is to trap dust that flies in during transport. Accordingly, the periods during which these regions operate are different from each other. Specifically, the period during which the first dust trapping region 3101 and the second dust trapping region 3102 operate is a period spanning a certain time from when the attraction units 3030 contact the magnet units 3031, and the period during which the mid-transportation dust trapping regions 3181 operate is a period during which the first substrate holder 3014 and the second substrate holder 3015 are transported individually or a period during which the first substrate holder 3014 and the second substrate holder 3015 are transported as the substrate holder pair 3018. The mid-transport dust trapping electrodes are wired such that voltage can be applied independently to the first dust trapping electrode 3111 and the second dust trapping electrode 3112, and the control section can operate the dust trapping regions selectively according to the circumstances.

If there is no dust generated by the bonding impact between the attraction units 3030 and the magnet units 3031 or if the amount of dust is small enough to ignore, the first dust trapping region 3101 and the second dust trapping region 3102 can be omitted. In this case, only the mid-transportation dust trapping region 3181 is provided, in order to trap the dust that flies in during transport.

In the embodiments and modifications described above, the first substrate 3016 and the second substrate 3017 are fixed respectively to the first substrate electrode 3116 and the second substrate electrode 3117 by electrostatic adhesion. However, the adhesion of the substrates is not limited to electrostatic adhesion. Suction holes may be formed in each holder to exert a suction force, thereby fixing the substrates thereto via suction adhesion. In this case as well, the dust floating in the dust trapping regions can be attracted by electrostatic force.

When the first substrate holder 3014 and the second substrate holder 3015 are used to manufacture a device via a substrate bonding apparatus 3010, the process for stacking the first substrate 3016 and the second substrate is as described below. This process includes mounting the first substrate 3016 on the first substrate holder 3014, mounting the second substrate 3017 on the second substrate holder 3015, and forming the first substrate holder 3014 and the second substrate holder 3015 integrally by engaging the attraction units 3030 with the magnet units 3031, while generating an electrostatic force via conduction through at least one of the first dust trapping electrode 3111 and the second dust trapping electrode 3112.

The process for transporting the first substrate 3016 as a substrate before being formed as a chip is as described below. This process includes mounting the first substrate 3016 on the first substrate holder 3014 and transporting the first substrate 3016 together with the first substrate holder 3014, while generating an electrostatic force via conduction through the mid-transport dust trapping electrode.

By including the dust flow inhibiting section described in each of the above embodiments, the occurrence of dust that can be generated by each process in the substrate bonding apparatus and the dust generated from the substrate holders themselves can be restricted, or can be prevented from flowing and sticking to the regions sandwiching the substrates.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A substrate holder pair comprising:
a first substrate holder that has a first holding portion holding a first substrate;
a second substrate holder that has a second holding portion holding a second substrate to be bonded with the first substrate and that, together with the first substrate holder, sandwiches the first substrate and the second substrate;
an engaging member that causes the first substrate holder to engage with the second substrate holder; and
a dust inhibiting section inhibits dust generated by the engaging of the engaging member from entering between the first holding portion and the second holding portion.

2. The substrate holder pair according to claim 1, wherein
the dust inhibiting section includes a dust trapping section that traps dust and is provided on at least one of the first substrate holder and the second substrate holder.

3. The substrate holder pair according to claim 2, wherein
the dust trapping section includes a first through-hole connected to a suction tube and provided between the engaging member and at least one of the first holding portion and the second holding portion, and sucks in dust through the first through-hole.

4. The substrate holder pair according to claim 3, wherein
the dust trapping section includes the first through-hole provided between the engaging member and the first holding portion of the first substrate holder and a second through-hole provided between the engaging member and the second holding portion of the second substrate holder, and
at least one of the first through-hole and the second through-hole is connected to the suction tube.

5. The substrate holder pair according to claim 3, wherein
the dust trapping section includes a third through-hole formed outside at least one of the first holding portion and the second holding portion at a position that is not between the engaging member and the at least one of the first holding portion and the second holding portion, and
the third through-hole is connected to a suction tube.

6. The substrate holder pair according to claim 3, wherein
the first substrate holder includes a third through-hole outside the first holding portion at a position that is not between the engaging member and the first holding portion,
the second substrate holder includes a fourth through-hole outside the second holding portion at a position that is not between the engaging member and the second holding portion, and
at least one of the third through-hole and the fourth through-hole is connected to a suction tube.

7. The substrate holder pair according to claim 2, wherein
the dust trapping section includes a dust trapping electrode that traps dust by generating electrostatic force and is provided between the engaging member and at least one of the first holding portion and the second holding portion.

8. The substrate holder pair according to claim 7, wherein
the dust trapping electrode is arranged to surround the engaging member.

9. The substrate holder pair according to claim 7, wherein
the dust trapping electrode includes a region located on a side of at least one of the first holding portion and the second holding portion in a transportation direction of the substrate holder pair.

10. The substrate holder pair according to claim 7, comprising a substrate electrode that adheres the substrate thereto by generating electrostatic force and is embedded in at least one of the first holding portion and the second holding portion.

11. The substrate holder pair according to claim 10, wherein
the substrate electrode and the dust trapping electrode have exterior contours that do not overlap each other in a direction perpendicular to the first holding portion and the second holding portion.

12. The substrate holder pair according to claim 10, wherein
electrostatic attractive force caused by the dust trapping electrode is greater than electrostatic attractive force of a mounting region caused by the substrate electrode.

13. The substrate holder pair according to claim 10, comprising a power supply terminal for supplying power in common to the substrate electrode and the dust trapping electrode.

14. The substrate holder pair according to claim 1, wherein
the dust inhibiting section includes a depressurizing means that causes atmospheric pressure in a region outside the first holding portion and the second holding portion to be less than atmospheric pressure between the first holding portion and the second holding portion.

15. The substrate holder pair according to claim 14, wherein
the depressurizing means includes a through-hole connected to a suction tube and provided between the engaging member and at least one of the first holding portion and the second holding portion.

16. The substrate holder pair according to claim 14, wherein
the depressurizing means includes a through-hole connected to a spout tube and provided between the engaging member and at least one of the first holding portion and the second holding portion.

17. The substrate holder pair according to claim 1, wherein
the dust inhibiting section includes a first wall portion that is provided between the engaging member and at least one of the first holding portion and the second holding portion and protrudes toward the at least one of the first holding portion and the second holding portion.

18. The substrate holder pair according to claim 17, wherein
protrusion distance of the first wall portion is greater than distance from the at least one of the first holding portion and the second holding portion to a contact surface between the first substrate and the second substrate.

19. The substrate holder pair according to claim 17, wherein
the first wall portion surrounds the at least one of the first holding portion and the second holding portion.

20. The substrate holder pair according to claim 17, wherein the dust inhibiting section includes:
the first wall portion provided between the engaging member and the first holding portion of the first substrate holder; and
a second wall portion provided between the engaging member and the second holding portion of the second substrate holder.

21. The substrate holder pair according to claim 20, wherein
the second wall portion does not interfere with the first wall portion when the first substrate holder and the second substrate holder are engaged with each other.

22. The substrate holder pair according to claim 20, wherein
the second wall portion surrounds the second holding portion.

23. The substrate holder pair according to claim 1, wherein
the dust inhibiting section includes a shield that covers a perimeter of an engaging section of the engaging member.

24. The substrate holder pair according to claim 23, wherein
the shield is formed integrally with the engaging member.

25. The substrate holder pair according to claim 23, comprising a charging section that charges the shield.

26. The substrate holder pair according to claim 23, wherein
the shield is attachable and detachable with respect to at least one of the first substrate holder and the second substrate holder.

27. The substrate holder pair according to claim 23, wherein
the engaging member includes a first engaging section provided outside the first holding portion of the first substrate holder and a second engaging section provided outside the second holding portion of the second substrate holder, and
the shield covers a perimeter of a contact surface between the first engaging section and the second engaging section.

28. The substrate holder pair according to claim 27, wherein
the second substrate holder includes a recessed portion into which the shield is withdrawn when the first engaging section engages with the second engaging section.

29. The substrate holder pair according to claim 1, wherein
the engaging member includes a first engaging section provided outside the first holding portion of the first substrate holder and a second engaging section provided outside the second holding portion of the second substrate holder, and
the dust inhibiting section includes a protruding portion provided on at least one of an engaging surface of the first engaging section and an engaging surface of the second engaging section, for achieving point contact or linear contact with the engaging surface of the other of the first engaging section and the second engaging section.

30. The substrate holder pair according to claim 29, wherein
the protruding portion is formed as a different member than the engaging member.

31. The substrate holder pair according to claim 29, wherein
the protruding portion includes at least three spherical members embedded in the engaging surface.

32. The substrate holder pair according to claim 1, wherein
the engaging member includes a first engaging section provided outside the first holding portion of the first substrate holder and a second engaging section provided outside the second holding portion of the second substrate holder, and
the dust inhibiting section inhibits dust generated by the engaging of the first engaging section and the second engaging section from entering between the first holding portion and the second holding portion.

33. The substrate holder pair according to claim 32, wherein
one of the first engaging section and the second engaging section includes a magnet and a support section that has a bonding surface and supports the magnet.

34. The substrate holder pair according to claim 33, wherein
the other of the first engaging section and the second engaging section is a ferroelectric body.

35. The substrate holder pair according to claim 32, wherein
one of the first engaging section and the second engaging section includes a through-hole through which passes a pillar member that prevents the first engaging section from engaging with the second engaging section.

36. The substrate holder pair according to claim 32, wherein
one of the first engaging section and the second engaging section is fixed to the first substrate holder or the second substrate holder via an elastic member having elasticity at least in a direction orthogonal to the first holding portion or the second holding portion.

37. A substrate holder pair comprising:
a first substrate holder that has a first holding portion contacting a first substrate;
a second substrate holder that has a second holding portion contacting a second substrate to be stacked on and bonded with the first substrate and that, together with the first substrate holder, sandwiches the first substrate and the second substrate;
a first engaging section provided on the first substrate holder; and
a second engaging section that engages with the first engaging section and is provided on the second substrate holder, wherein
a contact surface between the first engaging section and the second engaging section is positioned below a bonding surface between the first substrate and the second substrate in a direction of gravity.

38. The substrate holder pair according to claim 37, wherein
the contact surface between the first engaging section and the second engaging section is positioned below whichever of the first holding portion and the second holding portion is positioned lower, in the direction of gravity.

39. A substrate bonding apparatus comprising:
the substrate holder pair according to claim 1; and
a bonding section that bonds the first substrate held by the first substrate holder and the second substrate held by the second substrate holder to each other.

40. A substrate bonding apparatus comprising:
a first substrate holder that has a first holding portion contacting a first substrate;
a second substrate holder that has a second holding portion contacting a second substrate to be bonded with the first substrate and that, together with the first substrate holder, sandwiches the first substrate and the second substrate;
an engaging member that causes the first substrate holder and the second substrate holder to engage with each other;
a dust inhibiting section that inhibits dust generated by the engagement of the engaging member from entering between the first holding portion and the second holding portion; and
a bonding section that bonds the first substrate held by the first substrate holder and the second substrate held by the second substrate holder to each other.

41. A substrate bonding apparatus comprising:
a fixing section that fixes the first substrate and the second substrate, which is to be bonded to the first substrate, in a stacked state;
a dust inhibiting section that inhibits dust generated by the fixing of the fixing section from entering between the first substrate and the second substrate; and
a bonding section that bonds the first substrate and the second substrate to each other.

42. A device manufacturing method comprising manufacturing a device by stacking two substrates, the method comprising:
mounting a first substrate on a first substrate holder including a first holding portion that contacts the first substrate and a first engaging section provided outside the first holding portion;
mounting a second substrate on a second substrate holder including a second holding portion that contacts the second substrate and a second engaging section provided outside the second holding portion;
stacking the two substrates and sandwiching the two substrates with the first substrate holder and the second substrate holder; and
engaging the first engaging section and the second engaging section with each other, wherein
during the engaging, a dust inhibiting section is used to inhibit dust generated by the engaging of the first engaging section and the second engaging section from entering between the first holding portion and the second holding portion.

43. A substrate holder comprising:
a holder body having a holding region that holds a substrate;
a fixing member that is provided outside the holding region and fixes the substrate and another substrate in a stacked state; and
a dust inhibiting section that inhibits dust generated by the fixing of the fixing member from entering into the holding region.

44. The substrate holder according to claim 43, wherein
the dust inhibiting section includes a dust trapping section that traps dust and is provided on the holder body.

45. The substrate holder according to claim 44, wherein
the dust trapping section includes a through-hole connected to a suction tube and provided between the fixing member and the holding region, and sucks in dust through the through-hole.

46. The substrate holder according to claim 45, wherein
the dust trapping section includes a second through-hole formed outside the holding region at a position that is not between the fixing member and the holding region, and
the second through-hole is connected to a suction tube.

47. The substrate holder according to claim 44, wherein
the dust trapping section includes a dust trapping electrode that traps dust by generating electrostatic force and is provided between the fixing member and the holding region.

48. The substrate holder according to claim 47, wherein
the dust trapping electrode surrounds the fixing member.

49. The substrate holder according to claim 47, wherein
the dust trapping electrode is arranged on a side of the holding region in a transportation direction of the substrate holder.

50. A substrate holder that holds a substrate and is transported, comprising:
a holder body having a holding region that holds a substrate on a surface thereof; and
a dust trapping electrode that traps dust by generating electrostatic force and is embedded in a dust trapping region, which is positioned on a side of the holding region of the holder body in a transportation direction of the substrate holder.

51. The substrate holder according to claim 47, comprising a substrate electrode that adheres the substrate thereto by generating electrostatic force and is embedded in the holding region of the holder body.

52. The substrate holder according to claim 51, wherein
the substrate electrode and the dust trapping electrode have exterior contours that do not overlap each other in a direction perpendicular to the surface of the holder body.

53. The substrate holder according to claim 51, wherein
electrostatic attractive force caused by the dust trapping electrode is greater than electrostatic attractive force of the holding region caused by the substrate electrode.

54. The substrate holder according to claim 51, comprising a power supply terminal for supplying power in common to the substrate electrode and the dust trapping electrode.

55. The substrate holder according to claim 43, wherein
the dust inhibiting section includes a depressurizing means that causes atmospheric pressure in a region outside the holding region to be less than atmospheric pressure above the holding region.

56. The substrate holder according to claim 55, wherein
the depressurizing means includes a through-hole connected to a suction tube and provided between the fixing member and the holding region.

57. The substrate holder according to claim 55, wherein
the depressurizing means includes a through-hole connected to a spout tube and provided between the fixing member and the holding region.

58. The substrate holder according to claim 43, wherein
the dust inhibiting section includes a wall portion that rises up from the holder body and is provided between the fixing member and the holding region of the holder body.

59. The substrate holder according to claim 58, wherein
height of the wall portion from the holder body is greater than a distance from the holder body to the surface of the substrate.

60. The substrate holder according to claim 58, wherein
the wall portion surrounds the holding region.

61. The substrate holder according to claim 43, wherein
the dust inhibiting section includes a shield that covers a perimeter of a contact surface between the fixing member and a member to be fixed.

62. The substrate holder according to claim 61, wherein
the shield is formed integrally with the fixing member.

63. The substrate holder according to claim 61, comprising a charging section that charges the shield.

64. The substrate holder according to claim 61, wherein
the shield is attachable and detachable with respect to the holder body.

65. The substrate holder according to claim 43, wherein
the dust inhibiting section includes a protruding portion provided on a counterface surface of the fixing member facing a member to be fixed, for achieving point contact or linear contact with the member to be fixed.

66. The substrate holder according to claim 65, wherein
the protruding portion is formed as a different member than the fixing member.

67. The substrate holder according to claim 65, wherein
the protruding portion is formed by embedding at least three spherical members in the counterface surface.

68. The substrate holder according to claim 43, wherein
the fixing member includes a magnet and a support section that has a counterface surface and supports the magnet.

69. The substrate holder according to claim 43, wherein
the fixing member is a ferromagnetic body.

70. The substrate holder according to claim 69, wherein
the fixing member is fixed to the holder body via an elastic member having elasticity at least in a direction orthogonal to the holding region.

71. A substrate bonding apparatus comprising the substrate holder according to claim 43.

72. A substrate bonding apparatus comprising:
a holder body having a holding region that holds a substrate;
a fixing member that is provided outside the holding region and fixes the substrate and another substrate in a stacked state;
a dust inhibiting section that inhibits dust generated by the fixing of the fixing member from entering into the holding region; and
a bonding section that bonds the substrate held by the holder body to the other substrate.

73. A device manufacturing method comprising manufacturing a device by stacking two substrates, the method comprising:
mounting one of the two substrates on a holding region of a substrate holder;
stacking the one substrate held by the substrate holder and the other of the two substrates; and
fixing the two substrates in the stacked state using a fixing member provided on the substrate holder, wherein
during the fixing, a dust inhibiting section of the substrate holder is used to inhibit dust generated by the fixing of the fixing member from entering the holding region.
